(19) United States
(12) Patent Application Publication
(10) Pub. No.: US 2026/0156799 A1
(43) Pub. Date: Jun. 4, 2026

(54) SEMICONDUCTOR MEMORY DEVICE INCLUDING VERTICAL CHANNELS

(71) Applicant: Samsung Electronics Co., Ltd., Suwon-si (KR)

(72) Inventors: Taehyuk Kim, Suwon-si (KR); Suklae Kim, Suwon-si (KR); Uijin Kim, Suwon-si (KR); Taekyong Kim, Suwon-si (KR); Taejin Park, Suwon-si (KR)

(21) Appl. No.: 19/405,839

(22) Filed: Dec. 2, 2025

(30) Foreign Application Priority Data
Dec. 3, 2024 (KR) 10-2024-0177909

(51) Int. Cl. H10B 12/00; H01L 25/18; H10D 80/30

(52) U.S. Cl. CPC H10B 12/0335; H10B 12/315; H10B 12/482; H10B 12/488; H10D 80/30; H10W 90/00

(57) ABSTRACT

A semiconductor memory device includes a bit line extending in a horizontal direction, a contact plug, a contact isolation insulation layer surrounding the contact plug, the contact isolation insulation layer including a main isolation insulation layer and a sub isolation insulation layer, the sub isolation insulation layer disposed between a portion of the contact plug and the main isolation insulation layer, wherein a step shape is formed in the contact isolation insulation layer between an upper portion of the contact isolation insulation layer and a lower portion of the contact isolation insulation layer, a channel pattern disposed between the bit line and the contact plug and extending in a vertical direction, and a capacitor connected to the contact plug.

### CROSS-REFERENCE TO RELATED APPLICATION

This application is based on and claims priority under 35 U.S.C. § 119 to Korean Patent Application No. 10-2024-0177909, filed on Dec. 3, 2024, in the Korean Intellectual Property Office, the disclosure of which is incorporated by reference herein in its entirety.

### BACKGROUND

The inventive concept relates to a semiconductor memory device, and more particularly, to a semiconductor memory device including a vertical channel transistor.

As semiconductor memory devices are highly integrated, semiconductor devices included in semiconductor memory devices are being highly integrated. Therefore, in order to highly integrate semiconductor devices, vertical channel transistors vertically formed on a semiconductor substrate have been introduced instead of planar channel transistors one-dimensionally formed on a semiconductor substrate.

### SUMMARY

Aspects of the inventive concept provides a semiconductor memory device including a vertical channel transistor having enhanced operation reliability.

A semiconductor memory device according to an embodiment includes a bit line extending in a horizontal direction, a contact plug, a contact isolation insulation layer surrounding the contact plug, the contact isolation insulation layer including a main isolation insulation layer and a sub isolation insulation layer, the sub isolation insulation layer disposed between a portion of the contact plug and the main isolation insulation layer, wherein a step shape is formed in the contact isolation insulation layer between an upper portion of the contact isolation insulation layer and a lower portion of the contact isolation insulation layer, a channel pattern disposed between the bit line and the contact plug and extending in a vertical direction, and a capacitor connected to the contact plug.

A semiconductor memory device according to an embodiment includes a bit line extending in a first horizontal direction, a word line extending in a second horizontal direction differing from the first horizontal direction, on the bit line, a back gate electrode extending in the second horizontal direction on the bit line and disposed apart from the word line in the first horizontal direction, a contact plug in which a first conductive pattern and a second conductive pattern each including a semiconductor material and a third conductive pattern and a fourth conductive pattern each including a metal-based material are sequentially stacked, on the word line and the back gate electrode, a contact isolation insulation layer surrounding the contact plug and including a lower portion having a first minimum horizontal width in the first horizontal direction and an upper portion having a second minimum horizontal width in the first horizontal direction which is greater than the first minimum horizontal width, on the word line and the back gate electrode, a channel pattern including a first end connected to the bit line and a second, opposite end connected to the first conductive pattern of the contact plug and extending in a vertical direction, the channel pattern disposed between the word line and the back gate electrode, and a capacitor including a lower electrode connected to the fourth conductive pattern of the contact plug, an upper electrode on the lower electrode, and a capacitor dielectric layer disposed between the lower electrode and the upper electrode, wherein a boundary between the lower portion and the upper portion of the contact isolation insulation layer is disposed at a vertical level which is lower than an upper surface of the third conductive pattern and higher than a lower surface of the third conductive pattern.

A semiconductor memory device according to an embodiment includes a bit line extending in a first horizontal direction, a plurality of contact plugs where a first conductive pattern and a second conductive pattern each including a semiconductor material and a third conductive pattern and a fourth conductive pattern each including a metal-based material are sequentially stacked, a plurality of channel patterns, each disposed between the bit line and a respective first conductive pattern of a respective one of the plurality of contact plugs and extending in a vertical direction, a plurality of word lines and a plurality of back gate electrodes each extending in a second horizontal direction perpendicular to the first horizontal direction between the bit line and the plurality of contact plugs and disposed apart from one another with the plurality of channel patterns therebetween, a contact isolation insulation layer surrounding the plurality of contact plugs, on the plurality of channel patterns, the plurality of word lines, and the plurality of back gate electrodes, the contact isolation insulation layer including a main isolation insulation layer, including a plurality of first portions, each first portion at a first height above the bit line and having a first minimum horizontal width between two adjacent channel patterns in the first horizontal direction and including a plurality of second portions, each second portion at a second height above the bit line and below the first height and having a second minimum horizontal width between two adjacent channel patterns greater than the first minimum horizontal width, each second portion on a respective first portion, and a plurality of sub isolation insulation layers disposed between an upper partial portion of each of the plurality of contact plugs and the second portions of the main isolation insulation layer, and a plurality of capacitors including a plurality of lower electrodes respectively connected to the fourth conductive patterns of the plurality of contact plugs, an upper electrode on the plurality of lower electrodes, and a capacitor dielectric layer disposed between the plurality of lower electrodes and the upper electrode, wherein the plurality of sub isolation insulation layers contact an upper partial portion of the third conductive pattern of each of the plurality of contact plugs and the fourth conductive pattern.

### BRIEF DESCRIPTION OF THE DRAWINGS

Embodiments will be more clearly understood from the following detailed description taken in conjunction with the accompanying drawings in which:

FIG. 1 is a block diagram of a semiconductor memory device according to embodiments;

FIG. 2 is a perspective view schematically illustrating a semiconductor memory device according to embodiments;

FIGS. 3A and 3B are a cross-sectional view and a plan view illustrating a semiconductor memory device according to embodiments;

FIGS. 4A to 4H are cross-sectional views for describing a method of manufacturing a semiconductor memory device, according to embodiments;

FIGS. 5A to 5D are cross-sectional views of a semiconductor memory device according to embodiments;

FIGS. 6A and 6B are a cross-sectional view and a plan view of a semiconductor memory device according to embodiments;

FIGS. 7A and 7B are a cross-sectional view and a plan view of a semiconductor memory device according to embodiments;

FIG. 8 is a perspective view schematically illustrating a semiconductor memory device according to embodiments;

FIG. 9 is a cross-sectional view illustrating a semiconductor memory device according to embodiments;

FIG. 10 is a cross-sectional view illustrating a semiconductor memory device according to embodiments;

FIG. 11 is a perspective view schematically illustrating a semiconductor memory device according to embodiments; and

FIGS. 12A and 12B are cross-sectional views illustrating a semiconductor memory device according to embodiments.

### DETAILED DESCRIPTION OF THE EMBODIMENTS

Hereinafter, embodiments in the example embodiment will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The thickness of a layer may refer to the dimension in the direction perpendicular to the surface of the layer. The direction perpendicular to the surface may refer to its average orientation and not include minor unintentional deviations (e.g., pits) that may be formed during a manufacturing process.

An item, layer, or portion of an item or layer described as extending “lengthwise” in a particular direction has a length in the particular direction and a width perpendicular to that direction, where the length is greater than the width.

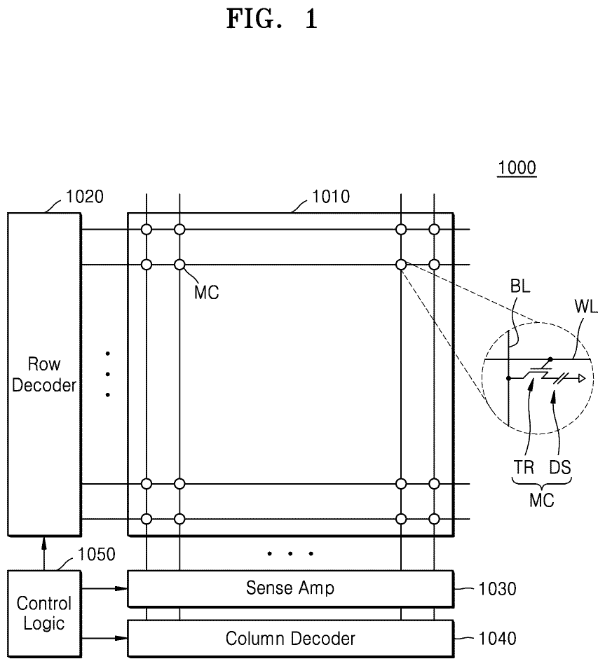

FIG. 1 is a block diagram of a semiconductor memory device 1000 according to embodiments.

Referring to FIG. 1, the semiconductor memory device 1000 may include a memory cell array 1010, a row decoder 1020, a sense amplifier 1030, a column decoder 1040, and a control logic 1050.

The memory cell array 1010 may include a plurality of memory cells MC, which are two-dimensionally or three-dimensionally arranged. Each of the memory cells MC may be connected between a word line WL and a bit line BL, which intersect or cross each other.

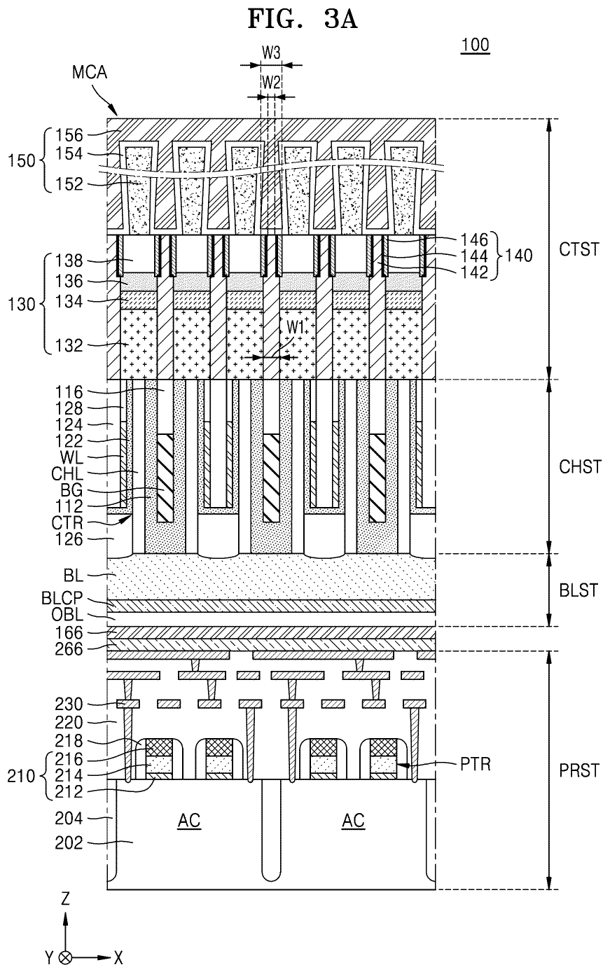

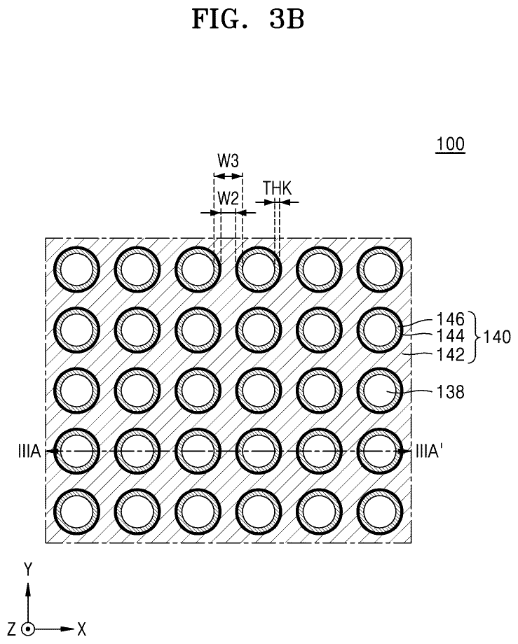

Each of the memory cells MC may include a selection element TR and a data storage element DS, and the selection element TR and the data storage element DS may be electrically and serially connected to each other. The selection element TR may be connected between the data storage element DS and the word line WL, and the data storage element DS may be connected to the bit line BL through the selection element TR. The selection element TR may be a field effect transistor (FET). In some embodiments, the selection element TR may be a vertical channel transistor CTR illustrated in FIG. 3A, but it is not limited thereto. In some embodiments, the data storage element DS may be a capacitor 150 illustrated in FIG. 3A, but it is not limited thereto. In some other embodiments, the data storage element DS may be a variable resistor pattern, which may be switched to two resistance states by an electrical pulse applied to a memory element. For example, the data storage element DS may include a phase-change material where a crystalline state changes based on the amount of current, such as perovskite compounds, transition metal oxide, magnetic materials, ferromagnetic materials, or antiferromagnetic materials.

The data storage element DS may be implemented as a magnetic tunnel junction pattern or a variable resistor. For example, the selection element TR may include a transistor, a gate electrode of the transistor may be connected to the word line WL, and source/drain terminals of the transistor may be respectively connected to the bit line BL and the data storage element DS.

The row decoder 1020 may decode an address input from the outside to select one word line WL from among word lines WL of the memory cell array 1010. An address decoded by the row decoder 1020 may be provided to a sub word line driver, and the sub word line driver may provide a certain voltage to each of the selected word line WL and unselected word lines WL, in response to control by control circuits.

The sense amplifier 1030 may sense and amplify a voltage difference between a reference bit line and a bit line BL selected based on an address decoded by the column decoder 1040 to output an amplified voltage difference.

The column decoder 1040 may provide a data transfer path between the sense amplifier 1030 and an external device (for example, a memory controller). The column decoder 1040 may decode an address input from the outside to select one bit line BL from among bit lines BL.

The control logic 1050 may generate control signals, which control operations of writing or reading data in or from the memory cell array 1010.

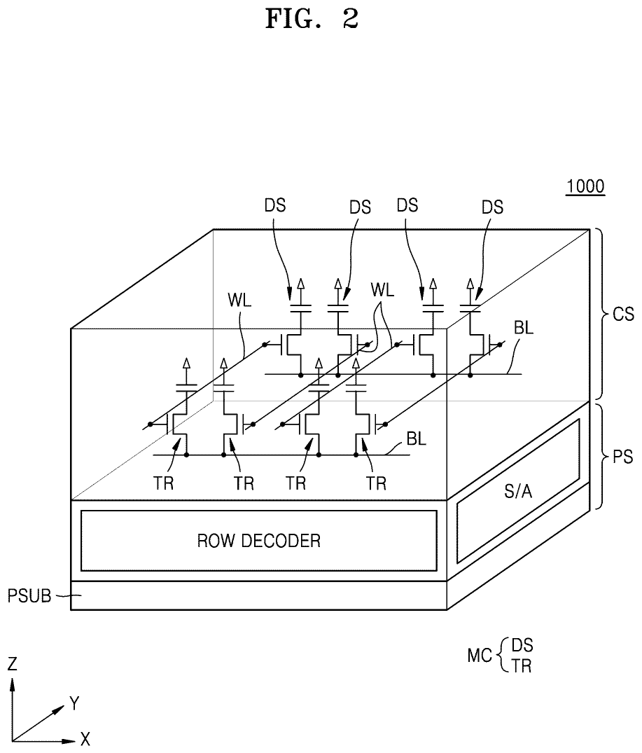

FIG. 2 is a perspective view schematically illustrating a semiconductor memory device 1000 according to embodiments.

Referring to FIG. 2, the semiconductor memory device 1000 may include a peripheral circuit structure PS and a cell array structure CS on the peripheral circuit structure PS, wherein the peripheral circuit structure PS includes a peripheral circuit substrate PSUB. The cell array structure CS may be bonded to the peripheral circuit structure PS so as to be stacked on the peripheral circuit structure PS.

The peripheral circuit structure PS may include a core and peripheral circuits, which are formed on the peripheral circuit substrate PSUB. The core and the peripheral circuits may include the row decoder 1020, the sense amplifier 1030, the column decoder 1040, and the control logic 1050 each described above with reference to FIG. 1. A decoder and a sense amplifier among the core and the peripheral circuits each included in the peripheral circuit structure PS are illustrated in FIG. 2. In FIG. 2, it is illustrated that the peripheral circuit substrate PSUB is disposed to be opposite to the cell array structure CS in a vertical direction (a Z direction) in the peripheral circuit structure PS, but the inventive concept is not limited thereto. In some embodiments, the peripheral circuit substrate PSUB may be disposed at a side facing the cell array structure CS in the vertical direction (the Z direction) in the peripheral circuit structure PS.

The cell array structure CS may include bit lines BL, word lines WL, and memory cells MC therebetween. The memory cells MC may be two-dimensionally or three-dimensionally arranged on a plane extending in a first horizontal direction (an X direction) and a second horizontal direction (a Y direction) intersecting each other to configure a memory cell array (1010 of FIG. 1). The bit lines BL may extend in the first horizontal direction (the X direction), and the word lines WL may extend in the second horizontal direction (the Y direction). Each of the memory cells MC may include a selection element TR and a data storage element DS.

In some embodiments, the selection element TR of each memory cell MC may include a vertical channel transistor (CTR of FIG. 3A). The vertical channel transistor (CTR of FIG. 3) may have a structure in which a channel length extends in the vertical direction (the Z direction). In some embodiments, the data storage element DS of each memory cell MC may be a capacitor.

FIGS. 3A and 3B are a cross-sectional view and a plan view illustrating a semiconductor memory device 100 according to embodiments. In detail, FIG. 3A is a cross-sectional view taken along line IIIA-IIIA′ of FIG. 3B, and FIG. 3B is a plan view illustrating a fourth conductive pattern 138 and a contact isolation insulation layer 140 each illustrated in FIG. 3A.

Referring to FIGS. 3A and 3B, the semiconductor memory device 100 may include a memory cell array structure MCA where a plurality of memory cells are disposed. For example, the plurality of memory cells may include a plurality of vertical channel transistors CTR. The memory cell structure MCA may be configured by stacking a bit line structure BLST, a channel structure CHST, and a capacitor structure CTST. A peripheral circuit structure PRST may include a peripheral circuit transistor PTR configured by a circuit gate structure 210. In some embodiments, the semiconductor memory device 100 may have a cell on periphery (CoP) structure where the memory cell array structure MCA and the peripheral circuit structure PRST overlap each other in a vertical direction (a Z direction). For example, the peripheral circuit transistor PTR configured by the circuit gate structure 210 may be configured to transfer a signal and/or power to a plurality of memory cells included in the memory cell array structure MCA. For example, the peripheral circuit transistor PTR configured by the circuit gate structure 210 may configure various circuits such as a command decoder, a control logic, an address buffer, a row decoder, a column decoder, a sense amplifier, and a data input/output (I/O) circuit. In some embodiments, the semiconductor memory device 100 may include a peripheral circuit region surrounding the memory cell array structure MCA in a one-dimensional viewpoint, instead of the peripheral circuit structure PRST. The peripheral circuit region may be a region where the peripheral circuit transistor PTR configured by the circuit gate structure 210 is provided.

In some embodiments, in the semiconductor memory device 100, the bit line structure BLST, the channel structure CHST, and the capacitor structure CTST may be sequentially stacked on the peripheral circuit structure PRST in the vertical direction (the Z direction).

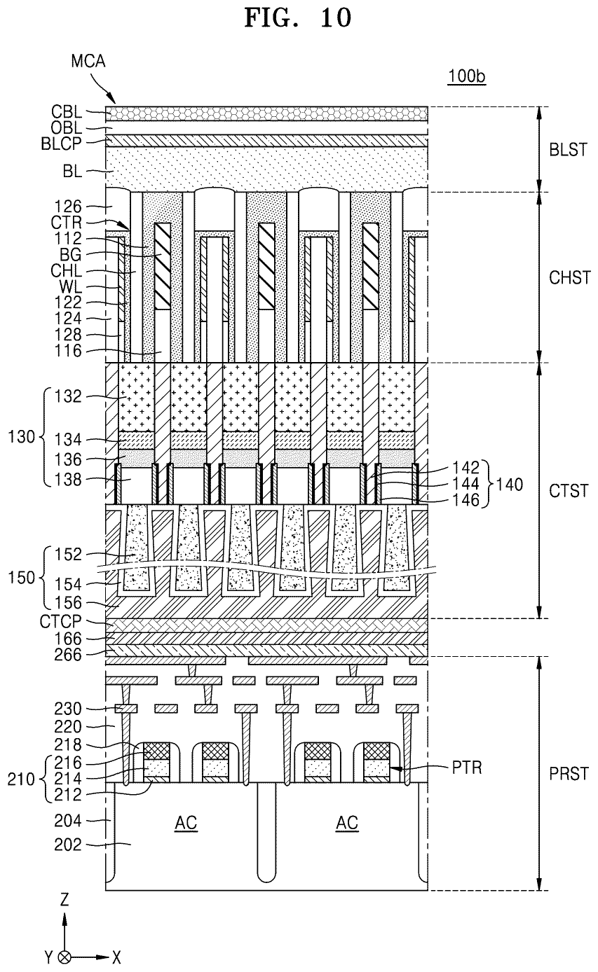

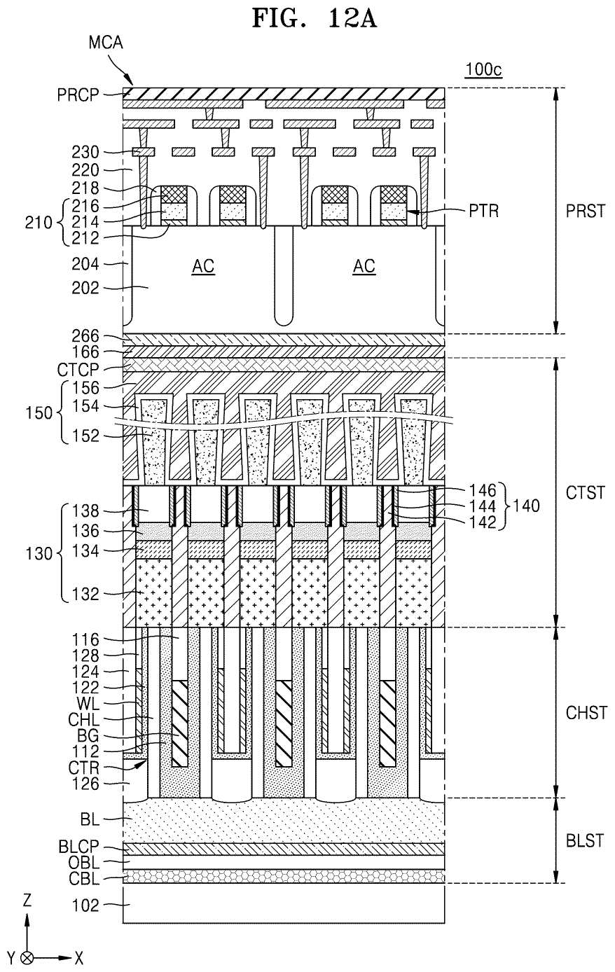

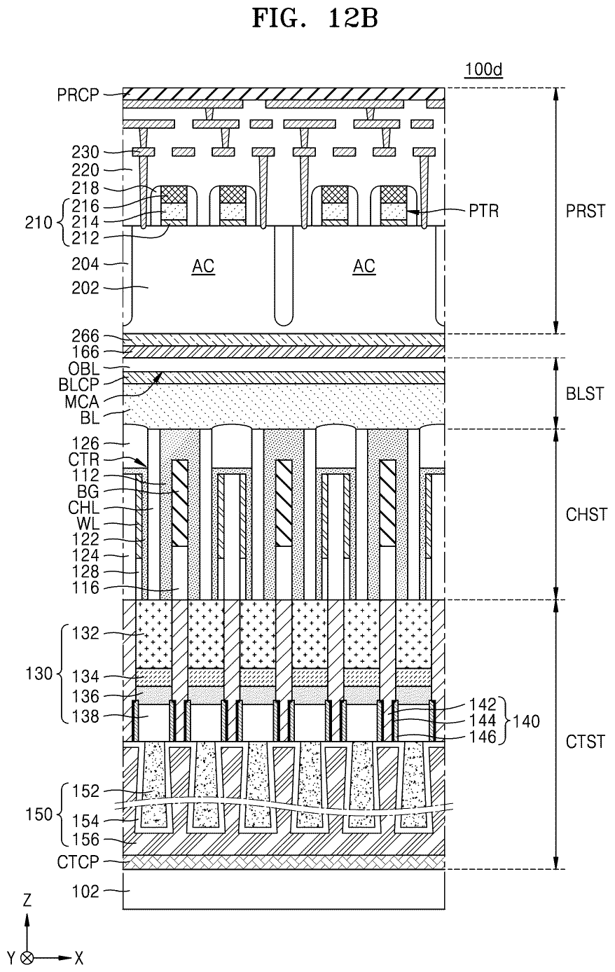

The bit line structure BLST may include a plurality of bit lines BL and an interlayer insulation layer OBL surrounding the plurality of bit lines BL. According to embodiments, the plurality of bit lines BL may extend lengthwise in a first horizontal direction (an X direction) and may be repeatedly arranged apart from one another in a second horizontal direction (a Y direction) intersecting the first horizontal direction (the X direction). In some embodiments, the plurality of bit lines BL may be apart from one another in the second horizontal direction (the Y direction) with the interlayer insulation layer OBL therebetween. The interlayer insulation layer OBL may fill all spaces between the plurality of bit lines BL and may cover lower portions (e.g., lower surfaces) of the plurality of bit lines BL. In some embodiments, a plurality of insulation capping lines BLCP may cover lower surfaces of the plurality of bit lines BL, and the interlayer insulation layer OBL may fill all spaces between the plurality of bit lines BL and the plurality of insulation capping lines BLCP and may cover lower portions of the plurality of insulation capping lines BLCP. In some embodiments, each of the plurality of bit lines BL may have a stack structure of a first line pattern, a second line pattern, and a third line pattern. For example, the first line pattern may include a semiconductor material, and each of the second line pattern and the third line pattern may include a metal-based material. The second line pattern and the third line pattern may include different kinds of metal-based materials. For example, the first line pattern may include doped polysilicon. For example, the second line pattern may include titanium nitride (TiN) or titanium silicon nitride (Ti—Si—N) (TSN), and the third line pattern may include tungsten (W) or tungsten silicide (WSiₓ). In some embodiments, the second line pattern may perform a function of a diffusion barrier. The insulation capping line BLCP may be disposed on the third line pattern. The first line pattern, the second line pattern, the third line pattern, and the insulation capping line BLCP may be sequentially disposed on the channel patterns CHL. In FIG. 3A, it is illustrated that the first line pattern, the second line pattern, the third line pattern, and the insulation capping line BLCP are sequentially disposed under the channel patterns CHL, but the inventive concept is not limited thereto. For example, in the bit line BL illustrated in FIGS. 10 and 12B, the first line pattern, the second line pattern, the third line pattern, and the insulation capping line BLCP may be sequentially disposed above the channel patterns CHL. The interlayer insulation layer OBL may include silicon oxide, silicon nitride, or a combination thereof. Each of the plurality of insulation capping lines BLCP may include silicon nitride.

The channel structure CHST may include a plurality of channel patterns CHL, a plurality of back gate electrodes BG, and a plurality of word lines WL. Each of the plurality of channel patterns CHL may extend in the vertical direction (the Z direction). Each of the plurality of back gate electrodes BG and the plurality of word lines WL may extend lengthwise in the second horizontal direction (the Y direction).

According to embodiments, the plurality of channel patterns CHL may be repeatedly arranged apart from one another in the first horizontal direction (the X direction) and the second horizontal direction (the Y direction) on the plurality of bit lines BL. Each of the uppermost plurality of channel patterns CHL may include a first end portion and a second end portion opposite to each other in the vertical direction (the Z direction). In FIG. 3A, each of the plurality of channel patterns CHL is illustrated as including a vertical extension portion extending in the vertical direction (the Z direction), but the embodiments are not limited thereto. In some embodiments, the plurality of channel patterns CHL may include a horizontal extension portion, which extends in the first horizontal direction (the X direction) from one end of the vertical extension portion. In some embodiments, the horizontal extension portion of the plurality of channel patterns CHL may be disposed at the first end portion. Alternatively, in some embodiments, the horizontal extension portion of the plurality of channel patterns CHL may be disposed at the second end portion. In each of the plurality of channel patterns CHL, the first end portion may be connected to one contact plug 130 selected from among the plurality of contact plugs 130, and the second end portion may be connected to one bit line BL selected from among the plurality of bit lines BL. In some embodiments, the channel pattern CHL may include a conductive region, for example, an impurity-doped well or an impurity-doped structure. Although not shown, an impurity region functioning as a source/drain region may be formed in each of the first end portion and the second end portion.

In some embodiments, each of the plurality of channel patterns CHL may include or may be a semiconductor material. For example, each of the plurality of channel patterns CHL may include or be single crystalline silicon, polycrystalline silicon, or amorphous silicon. In some other embodiments, each of the plurality of channel patterns CHL may include at least one selected from among germanium (Ge), silicon germanium (SiGe), silicon carbide (SiC), gallium arsenide (GaAs), indium arsenide (InAs), and indium phosphide (InP). In some other embodiments, each of the plurality of channel patterns CHL may include an oxide semiconductor material. Each of the plurality of channel patterns CHL may include at least one of a binary or ternary oxide semiconductor material including a first metal element, a ternary oxide semiconductor material including a first metal element and a second metal element which differ, and a quaternary oxide semiconductor material including the first metal element, the second metal element, and a third metal element which differ.

The binary or ternary oxide semiconductor material may be, for example, one of ZnO (zinc oxide, ZnₓO), GaO (gallium oxide, GaₓO), TiO (titanium oxide, TiₓO), ZnON (zinc oxynitride, ZnₓO_{y}N), IZO (indium zinc oxide, InₓZn_{y}O), GZO (gallium zinc oxide, GaₓZn_{y}O), TZO (tin zinc oxide, SnₓZn_{y}O), and TGO (tin gallium oxide, SnₓGa_{y}O), but is not limited thereto. The quaternary oxide semiconductor material may be, for example, one of IGZO (indium gallium zinc oxide, InₓGa_{Y}Zn_{z}O), IGSO (indium gallium silicon oxide, InₓGa_{y}Si_{z}O), ITZO (indium tin zinc oxide, InₓSn_{Y}Zn_{z}O), IGTO (indium gallium tin oxide, InₓGa_{y}Sn_{z}O), ZZTO (zirconium zinc tin oxide, Zr_{X}Zn_{y}Sn_{z}O), HIZO (hafnium indium zinc oxide, HfₓIn_{Y}Zn_{z}O), GZTO (gallium zinc tin oxide, Ga_{X}Zn_{y}Sn_{z}O), AZTO (aluminum zinc tin oxide, Al_{X}Zn_{y}Sn_{z}O), and YGZO (ytterbium gallium zinc oxide, YbₓGa_{Y}Zn_{z}O), and IAZO (indium aluminum zinc oxide), but is not limited thereto.

In some embodiments, each of the plurality of channel patterns CHL may include a crystalline oxide semiconductor material, or an amorphous oxide semiconductor material. When each of the plurality of channel patterns CHL includes an oxide semiconductor material, each of the plurality of channel patterns CHL may have at least one of single crystalline, polycrystalline, spinel, and c-axis aligned crystalline (CAAC). In some embodiments, each of the plurality of channel patterns CHL may be configured by stacking at least two layers which include a first layer including a crystalline oxide semiconductor material and a second layer including an amorphous oxide semiconductor material. For example, each of the plurality of channel patterns CHL may be configured by sequentially stacking the first layer including a crystalline oxide semiconductor material, the second layer including an amorphous oxide semiconductor material, and a third layer including a crystalline oxide semiconductor material.

Each of the plurality of back gate electrodes BG and the plurality of word lines WL may extend lengthwise in the second horizontal direction (the Y direction) at a vertical height between the plurality of bit lines BL and the plurality of contact plugs 130. The plurality of back gate electrodes BG and the plurality of word lines WL may be apart from one another in the first horizontal direction (the X direction). According to embodiments, each of the plurality of channel patterns CHL may be disposed between one back gate electrode BG and one word line WL adjacent to each other in the first horizontal direction (the X direction), on a corresponding bit line BL among the plurality of bit lines BL. For example, each of the plurality of channel patterns CHL may face one gate electrode BG at one side in the first horizontal direction (the X direction) and may face one word line WL at the other side. In some embodiments, one back gate electrode BG and a pair of word lines WL may be alternately arranged between consecutive pairs of channel patterns CHL adjacent to each other in the first horizontal direction (the X direction). According to embodiments, a pair of channel patterns CHL may be disposed at both sides (e.g., opposite sides) of each of the plurality of back gate electrodes BG in the first horizontal direction (the X direction), and a pair of word lines WL may be disposed apart from a first adjacent corresponding back gate electrode BG among the plurality of back gate electrodes BG with a first channel pattern CHL therebetween, and may be disposed apart from a second adjacent corresponding back gate electrode BG among the plurality of back gate electrodes BG with a second channel pattern CHL therebetween. For example, one channel pattern CHL, a pair of word lines WL, and one other channel pattern CHL may be sequentially disposed in the first horizontal direction (the X direction) between a pair of back gate electrodes BG adjacent to each other among back gate electrodes BG in the first horizontal direction (the X direction). A pair of word lines WL disposed between two channel patterns CHL adjacent to each other among channel patterns CHL in the first horizontal direction (the X direction) may be apart from each other in the first horizontal direction (the X direction) with an isolation insulation pattern 124 therebetween.

In some embodiments, each of the plurality of back gate electrodes BG may include or be formed of a metal, conductive metal nitride, doped polysilicon, or a combination thereof. For example, each of the plurality of back gate electrodes BG may include or be titanium (Ti), titanium nitride (TiN), tantalum (Ta), tantalum nitride (TaN), molybdenum (Mo), ruthenium (Ru), tungsten (W), tungsten nitride (WN), titanium silicon nitride (TiSiN), tungsten silicon nitride (WSiN), doped polysilicon, or a combination thereof, but is not limited thereto. Each of the plurality of word lines WL may include or be formed of a metal, conductive metal nitride, doped polysilicon, or a combination thereof. For example, each of the plurality of word lines WL may include or be Ti, TiN, Ta, TaN, Mo, Ru, W, WN, TiSiN, WSIN, doped polysilicon, or a combination thereof, but is not limited thereto.

The channel structure CHST may include a plurality of back gate dielectric layers 112 respectively covering both (e.g., opposite) sidewalls of each of the plurality of back gate electrodes BG in the first horizontal direction (the X direction). Each of the plurality of back gate dielectric layers 112 may be disposed between one back gate electrode BG and one channel pattern CHL adjacent thereto. For example, each of the plurality of back gate dielectric layers 112 may contact a corresponding back gate electrode BG and a corresponding channel pattern CHL. In FIG. 3A, it is illustrated that the back gate dielectric layer 112 is disposed between the back gate electrode BG and the bit line BL, but the inventive concept is not limited thereto. For example, an insulation pattern may be further disposed between the back gate electrode BG and the bit line BL. The back gate electrode BG may be apart from the plurality of bit lines BL in the vertical direction (the Z direction) with the back gate dielectric layer 112 and/or the insulation pattern therebetween. In some embodiments, the capping insulation pattern 116 may be disposed between the back gate electrode BG and the plurality of contact plugs 130. In some embodiments, the capping insulation pattern 116 and the back gate electrode BG may be disposed to overlap each other along the vertical direction (the Z direction), and each of both sidewalls of each of the capping insulation pattern 116 and the back gate electrode BG in the first horizontal direction (the X direction) may contact the back gate dielectric layer 112 and may be covered by the back gate dielectric layer 112. The back gate electrode BG may be apart from the plurality of contact plugs 130 in the vertical direction (the Z direction) with the capping insulation pattern 116 therebetween. In some embodiments, the capping insulation pattern 116 may include or be formed of silicon oxide, silicon nitride, or a combination thereof.

The channel structure CHST may include a plurality of gate dielectric layers 122 respectively disposed between the plurality of word lines WL and the plurality of channel patterns CHL adjacent thereto. A pair of gate dielectric layers 122 may be disposed between a pair of channel patterns CHL which are apart from each other with the isolation insulation pattern 124 therebetween and are adjacent to each other in the first horizontal direction (the X direction). A pair of word lines WL may be disposed between a pair of gate dielectric layers 122. Each of a pair of gate dielectric layers 122 may be disposed between one word line WL and channel patterns CHL, which are disposed adjacent thereto and are arranged in the second horizontal direction (the Y direction), of the plurality of channel patterns CHL and may contact the word line WL and the channel patterns CHL.

According to embodiments, one sidewall of each of the plurality of channel patterns CHL in the first horizontal direction (the X direction) may contact one back gate dielectric layer 112 selected from among the plurality of back gate dielectric layers 112, and the other sidewall may contact one gate dielectric layer 122 selected from among the plurality of gate dielectric layers 122. According to embodiments, each of both sidewalls of each of the plurality of channel patterns CHL in the second horizontal direction (the Y direction) may contact a corresponding gate dielectric layer 122 among the plurality of gate dielectric layers 122 and may face a corresponding word line WL among the plurality of word lines WL with the gate dielectric layer 122 therebetween.

According to embodiments, the isolation insulation pattern 124 may be disposed between a pair of word lines WL disposed between a pair of channel patterns CHL adjacent to each other. A first buried insulation pattern 126 may be disposed between a pair of word lines WL and the bit line BL, and a second buried insulation patterns 128 may be disposed between the word line WL and the plurality of contact plugs 130. A pair of second buried insulation patterns 128 may be apart from each other in the first horizontal direction (the X direction) with the isolation insulation pattern 124 therebetween. The first buried insulation pattern 126, a pair of word lines WL, and a pair of second buried insulation patterns 128 may be disposed to overlap each other along the vertical direction (the Z direction) between a pair of channel patterns CHL adjacent to each other in the first horizontal direction (the X direction). A pair of word lines WL and the isolation insulation pattern 124 may be apart from the plurality of bit lines BL in the vertical direction (the Z direction) with the first buried insulation pattern 126 therebetween. A pair of word lines WL may be apart from the plurality of contact plugs 130 in the vertical direction (the Z direction) with the second buried insulation pattern 128 therebetween. In some embodiments, each of the isolation insulation pattern 124, the first buried insulation pattern 126, and the second buried insulation pattern 128 may include or be formed of silicon oxide, silicon nitride, or a combination thereof.

According to embodiments, each of the gate dielectric layer 122 and the back gate dielectric layer 112 may include or be a silicon oxide layer, a high-k dielectric layer, or a combination thereof. The term “high-k dielectric layer” used herein may denote a dielectric layer having a dielectric constant which is higher than that of silicon oxide. In embodiments, each of the gate dielectric layer 122 and the back gate dielectric layer 112 may include or be formed of at least one material selected from among hafnium oxide (HfO), hafnium silicate (HfSiO), hafnium oxide nitride (HfON), hafnium silicon oxide nitride (HfSiON), lanthanum oxide (LaO), lanthanum aluminum oxide (LaAlO), zirconium oxide (ZrO), zirconium silicon oxide (ZrSiO), zirconium oxide nitride (ZrON), zirconium silicon oxide nitride (ZrSiON), tantalum oxide (TaO), titanium oxide (TiO), barium strontium titanium oxide (BaSrTiO), barium titanium oxide (BaTiO), lead zirconate titanate (PZT), strontium tantalate bismuth (STB), bismuth iron oxide (BFO), strontium titanium oxide (SrTiO), yttrium oxide (YO), aluminum oxide (AlO), and lead scandium tantalum oxide (PbScTaO). The plurality of back gate electrodes BG, the plurality of word lines WL, the plurality of channel patterns CHL, the plurality of back gate dielectric layers 112, and the plurality of gate dielectric layers 122, disposed between the plurality of bit lines BL and the plurality of contact plugs 130, may form a plurality of vertical channel transistors CTR. Herein, the plurality of vertical channel transistors CTR may be referred to as a vertical channel transistor structure.

In FIG. 3A, it is illustrated that lower surfaces of the plurality of back gate electrodes BG are disposed closer to the plurality of bit lines BL than the plurality of word lines WL are to the plurality of bit lines BL, but the inventive concept is not limited thereto. For example, the lower surfaces of the plurality of back gate electrodes BG may be disposed at the same vertical level as lower surfaces of the plurality of word lines WL, or may be disposed farther away from the plurality of bit lines BL than lower surfaces of the plurality of word lines WL are to the plurality of bit lines BL.

The capacitor structure CTST may include the plurality of contact plugs 130 and the plurality of capacitors 150, which are disposed on the plurality of channel patterns CHL. Each of the plurality of contact plugs 130 may be disposed on a corresponding channel pattern CHL among the plurality of channel patterns CHL. Each of the plurality of channel patterns CHL may extend in the vertical direction (the Z direction) between one bit line BL selected from among the plurality of bit lines BL and one contact plug 130 selected from among the plurality of contact plugs 130.

According to embodiments, the plurality of contact plugs 130 may be apart from the plurality of bit lines BL in the vertical direction (the Z direction) with the plurality of channel patterns CHL therebetween. The plurality of contact plugs 130 may be arranged in a matrix array so as to be apart from one another in the first horizontal direction (the X direction) and the second horizontal direction (the Y direction). The plurality of contact plugs 130 may be respectively connected to the plurality of channel patterns CHL one-by-one.

In some embodiments, each of the plurality of contact plugs 130 may include or be formed of metal, conductive metal nitride, doped polysilicon, or a combination thereof. For example, each of the plurality of contact plugs 130 may include or be Ti, TiN, Ta, TaN, Mo, Ru, W, WN, Co, Ni, TiSi, TiSiN, WSi, WSIN, TaSi, TaSIN, RuTiN, CoSi, NiSi, doped polysilicon, or a combination thereof.

In some embodiments, each of the plurality of contact plugs 130 may include a first conductive pattern 132, a second conductive pattern 134, a third conductive pattern 136, and a fourth conductive pattern 138, which are sequentially stacked on each of the plurality of channel patterns CHL. The first conductive pattern 132 and the second conductive pattern 134 may include or be a semiconductor material, and the third conductive pattern 136 and the fourth conductive pattern 138 may include or be a metal-based material. For example, the first conductive pattern 132 may be undoped polysilicon, the second conductive pattern 134 may be doped polysilicon, the third conductive pattern 136 may be metal silicide, and the fourth conductive pattern 138 may be metal, but the inventive concept is not limited thereto. For example, each of the plurality of contact plugs 130 may include the second conductive pattern 134 including doped polysilicon, the third conductive pattern 136 including metal silicide, and the fourth conductive pattern 138 including metal, which are sequentially stacked on each of the plurality of channel patterns CHL and do not include undoped polysilicon. A stack structure of the first conductive pattern 132 and the second conductive pattern 134, or the second conductive pattern 134 if included without the first conductive pattern 132 may be a buried contact BC, a stack structure of the fourth conductive pattern 138 may be a landing pad LP, and the third conductive pattern 136 may be a metal silicide layer disposed between the buried contact and the landing pad. The stack structure of the first conductive pattern 132 and the second conductive pattern 134, or the second conductive pattern 134 if included without the first conductive pattern 132 may be a semiconductor pattern, the third conductive pattern 136 may be a metal silicide pattern, and the fourth conductive pattern 138 may be a metal pattern.

The capacitor structure CTST may include a contact isolation insulation layer 140 surrounding each contact plug of the plurality of contact plugs 130. Each of the plurality of contact plugs 130 may pass through the contact isolation insulation layer 140 and may contact one selected channel pattern CHL. The plurality of contact plugs 130 may be apart from one another in the first horizontal direction (the X direction) and the second horizontal direction (the Y direction) with the contact isolation insulation layer 140 therebetween. In some embodiments, the contact isolation insulation layer 140 may include silicon nitride.

The contact isolation insulation layer 140 may include a main isolation insulation layer 142 and a plurality of sub isolation insulation layers 146. In some embodiments, the contact isolation insulation layer 140 may further include a plurality of interface insulation layers 144 disposed between the main isolation insulation layer 142 and the plurality of sub isolation insulation layers 146. For example, the plurality of interface insulation layers 144 may form an interface between the main isolation insulation layer 142 and the plurality of sub isolation insulation layers 146. Each of the main isolation insulation layer 142 and the plurality of sub isolation insulation layers 146 may include or be nitride, and each of the plurality of interface insulation layers 144 may include or be oxide. For example, each of the main isolation insulation layer 142 and the plurality of sub isolation insulation layers 146 may include or be silicon nitride, and each of the plurality of interface insulation layers 144 may include or be silicon oxide. In some embodiments, each of the plurality of interface insulation layers 144 may include or be a natural oxide.

The contact isolation insulation layer 140 may fill a space between the plurality of contact plugs 130. For example, the plurality of contact plugs 130 may fill a plurality of contact holes, which are spaces limited by the contact isolation insulation layer 140. The plurality of sub isolation insulation layers 146 may cover upper partial portions of surfaces of the plurality of contact plugs 130 exposed at sidewalls of a plurality of spaces limited by the main isolation insulation layer 142. For example, the plurality of sub isolation insulation layers 146 may surround and may contact upper portions of the plurality of contact plugs 130, and the main isolation insulation layer 142 may surround the plurality of sub isolation insulation layers 146 covering upper portions of the plurality of contact plugs 130 and may also surround lower portions of the plurality of contact plugs 130. When each of the plurality of contact plugs 130 has a circular horizontal shape, each of the plurality of sub isolation insulation layers 146 may have a ring-shaped horizontal shape.

The main isolation insulation layer 142 may fill a portion of the space between the plurality of contact plugs 130. For example, the main isolation insulation layer 142 may fill a space between a plurality of first conductive patterns 132 and may fill a space between a plurality of second conductive patterns 134, each of which conductive pattern in included in one of the plurality of contact plugs 130, and may fill a portion of a space between a plurality of third conductive patterns 136 and may fill a space between a plurality of fourth conductive patterns 138, each of which conductive pattern is included in one of the plurality of contact plugs 130. The plurality of sub isolation insulation layers 146 may fill another partial portion of the space between the plurality of third conductive patterns 136 and may fill another partial portion of the space between the plurality of fourth conductive patterns 138, which are included in the plurality of contact plugs 130. An upper surface (e.g., uppermost surface or upper end surface) of the main isolation insulation layer 142 and an upper end (e.g., uppermost surface or upper end surface) of each of the plurality of sub isolation insulation layers 146 may be disposed at the same vertical level. A lower end (e.g., lowermost surface or lower end surface) of each of the plurality of sub isolation insulation layers 146 may be disposed at a vertical level which is higher than a lower surface (e.g., lowermost surface or lower end surface) of the main isolation insulation layer 142. The lowermost end of each of the plurality of sub isolation insulation layers 146 may be disposed at a vertical level which is lower than or equal to a lower surface of each of the plurality of fourth conductive patterns 138, and is lower than or equal to an upper surface of each of the plurality of third conductive patterns 136, and may be disposed at a vertical level which is higher than or equal to a lower surface of each of the plurality of third conductive patterns 136, and therefore higher than an upper surface of each of the plurality of second conductive patterns 134. The upper surface and the lower surface of the main isolation insulation layer 142 may be respectively disposed at one end and the other end of the main isolation insulation layer 142 in the vertical direction (the Z direction), the upper end and the lower end of the sub isolation insulation layer 146 may be respectively disposed at one end and the other end of the sub isolation insulation layer 146 in the vertical direction (the Z direction), the upper surface and the lower surface of the fourth conductive pattern 138 may be respectively disposed at one end and the other end of the fourth conductive pattern 138 in the vertical direction (the Z direction), the upper surface and the lower surface of the third conductive pattern 136 may be respectively disposed at one end and the other end of the third conductive pattern 136 in the vertical direction (the Z direction), the upper surface and the lower surface of the second conductive pattern 134 may be respectively disposed at one end and the other end of the second conductive pattern 134 in the vertical direction (the Z direction), and the upper surface and the lower surface of the first conductive pattern 132 may be respectively disposed at one end and the other end of the first conductive pattern 132 in the vertical direction (the Z direction).

In some embodiments, the lowermost end of each of the plurality of sub isolation insulation layers 146 may be disposed at a vertical level which is lower than the upper surface of each of the plurality of third conductive patterns 136 and which is higher than the lower surface of each of the plurality of third conductive patterns 136. For example, the plurality of sub isolation insulation layers 146 may extend to a region between the main isolation insulation layer 142 and the plurality of third conductive patterns 136 from a region between the main isolation insulation layer 142 and the plurality of fourth conductive patterns 138. In some embodiments, the plurality of sub isolation insulation layers 146 may extend to a region between the main isolation insulation layer 142 and the plurality of third conductive patterns 136 from a region between the main isolation insulation layer 142 and the plurality of fourth conductive patterns 138 and may not extend to the plurality of second conductive patterns 134.

The plurality of first conductive patterns 132 and the plurality of second conductive patterns 134 may contact the main isolation insulation layer 142. The plurality of fourth conductive patterns 138 may contact the plurality of sub isolation insulation layers 146, may be disposed between the plurality of sub isolation insulation layers 146, and may be apart from the main isolation insulation layer 142. In some embodiments, the plurality of third conductive patterns 136 may contact the main isolation insulation layer 142 and the plurality of sub isolation insulation layers 146. For example, lower portions of the plurality of third conductive patterns 136 may contact the main isolation insulation layer 142, and the upper portions of the plurality of third conductive patterns 136 may contact the plurality of sub isolation insulation layers 146, may be disposed between the plurality of sub isolation insulation layers 146, and may be apart from the main isolation insulation layer 142.

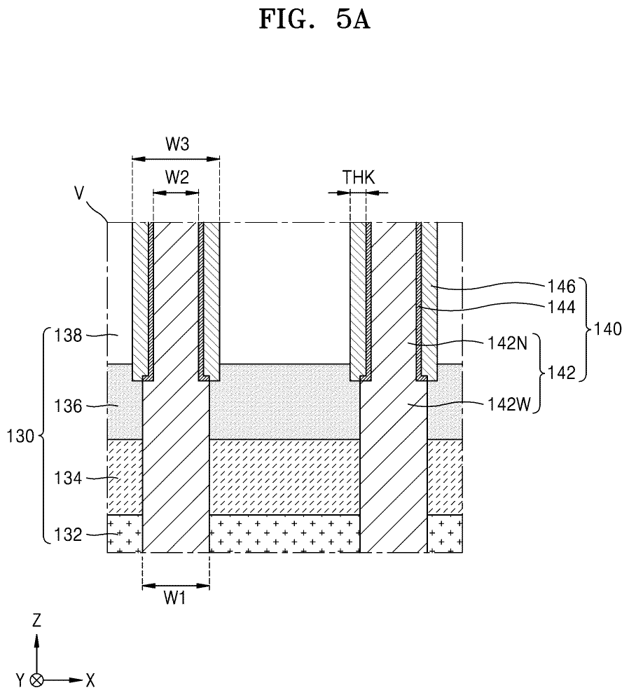

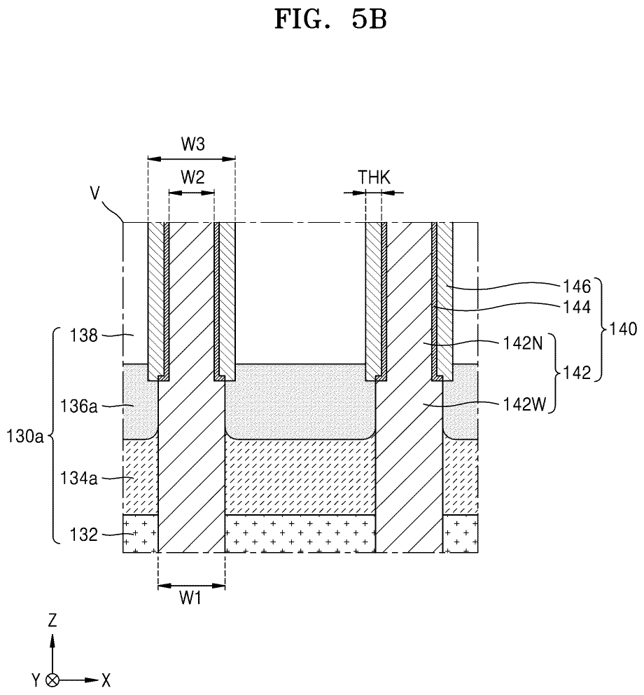

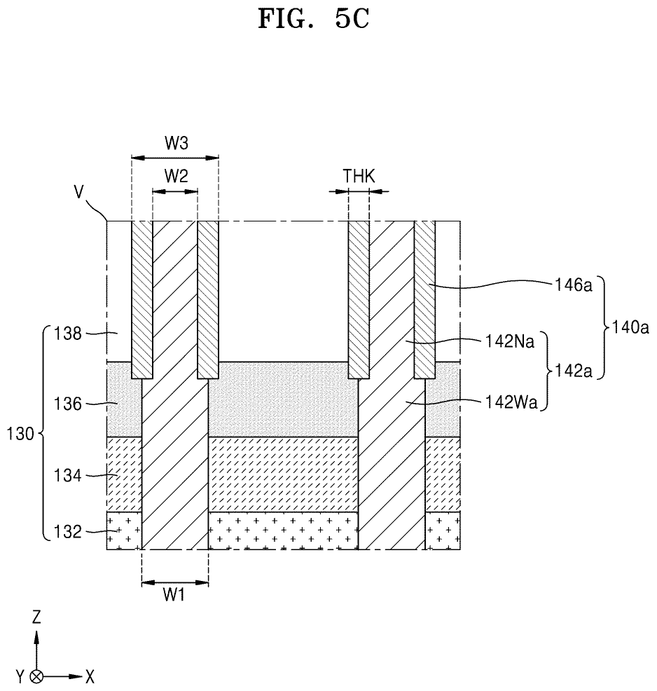

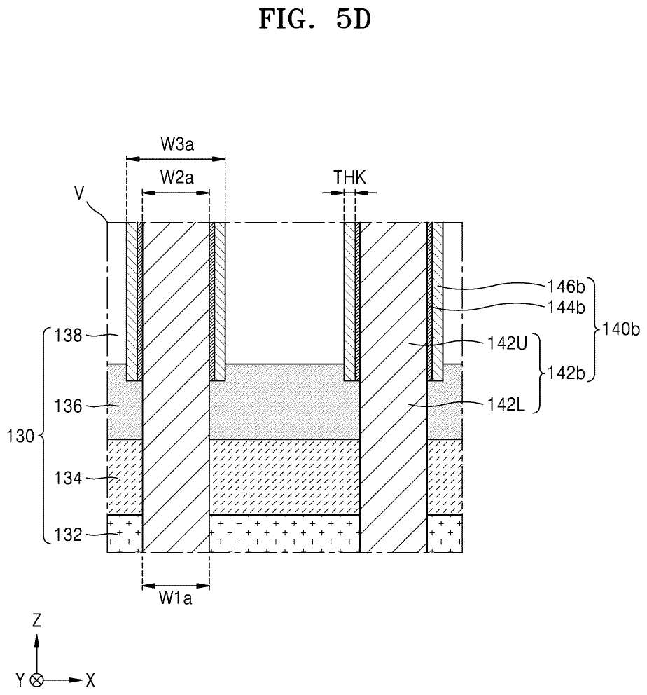

In some embodiments, a lower portion of the main isolation insulation layer 142 may have a first horizontal width W1, and an upper portion of the main isolation insulation layer 142 may have a second horizontal width W2, which is less than the first horizontal width W1. The sub isolation insulation layer 146 may have a certain thickness THK and may cover an upper portion of the main isolation insulation layer 142. A lower portion of the contact isolation insulation layer 140 may have the first horizontal width W1, and an upper portion of the contact isolation insulation layer 140 may have a third horizontal width W3, which is greater than the first horizontal width W1. The contact isolation insulation layer 140 will be described below in more detail with reference to FIG. 5A.

The plurality of capacitors 150 may include a plurality of lower electrodes 152 respectively connected to the plurality of contact plugs 130, a capacitor dielectric layer 154 conformally covering a surface of each of the plurality of lower electrodes 152, and an upper electrode 156 covering the plurality of lower electrodes 152 with the capacitor dielectric layer 154 therebetween. Each of the plurality of lower electrodes 152 may be connected to a channel pattern CHL through one contact plug 130 selected from among the plurality of contact plugs 130. The fourth conductive pattern 138 included in each of the plurality of contact plugs 130 may function as a landing pad which contacts one lower electrode 152 selected from among the plurality of lower electrodes 152.

Each of the plurality of lower electrodes 152 may have a pillar shape where an inner portion is filled to include a horizontal cross-sectional surface having a circular shape, but is not limited thereto. In some embodiments, each of the plurality of lower electrodes 152 may have a cylinder shape where a lower portion is closed. In some embodiments, the plurality of lower electrodes 152 may be arranged in a matrix form where the plurality of lower electrodes 152 are arranged in one row in each of the first horizontal direction (the X direction) and the second horizontal direction (the Y direction). In some other embodiments, the plurality of lower electrodes 152 may be arranged in a honeycomb shape where the plurality of lower electrodes 152 are arranged in zigzags in the first horizontal direction (the X direction) or the second horizontal direction (the Y direction). The plurality of lower electrodes 152 may include or be formed of, for example, impurity-doped silicon, metal such as tungsten or copper, or a conductive metal compound such as titanium nitride.

The capacitor dielectric layer 154 may conformally cover surfaces of the plurality of lower electrodes 152. In some embodiments, the capacitor dielectric layer 154 may include or be a high-k dielectric layer. In some embodiments, the capacitor dielectric layer 154 may include or be metal oxide including at least one metal selected from among hafnium (Hf), zirconium (Zr), niobium (Nb), cerium (Ce), lanthanum (La), tantalum (Ta), and titanium (Ti). In some embodiments, each of the plurality of lower electrodes 152 and the upper electrode 156 may include or be metal, conductive metal oxide, conductive metal nitride, conductive metal oxynitride, or a combination thereof. In some embodiments, each of the plurality of lower electrodes 152 and the upper electrode 156 may include or be formed of Nb, Nb oxide, Nb nitride, Nb oxynitride, Ti, Ti oxide, Ti nitride, Ti oxynitride, Co, Co oxide, Co nitride, Co oxynitride, Sn, Sn oxide, Sn nitride, Sn oxynitride, or a combination thereof. In some embodiments, each of the plurality of lower electrodes 152 and the upper electrodes 156 may include or be formed of TaN, TiAlN, TaAlN, V, VN, Mo, MoN, W, WN, Ru, RuO₂, SrRuO₃, Ir, IrO₂, Pt, PtO, SRO(SrRuO₃), BSRO((Ba,Sr)RuO₃), CRO(CaRuO₃), LSCO((La,Sr)CoO₃), or a combination thereof. However, a material of each of the plurality of lower electrodes 152 and the upper electrode 156 is not limited to the above descriptions. In some embodiments, the upper electrode 156 may further include at least one of a doped semiconductor material layer and an interface layer, in addition to a metal material, and may have a stack structure thereof. The doped semiconductor material layer may include, for example, at least one of doped polysilicon and doped polycrystalline silicon germanium (poly-SiGe). The main electrode layer may include a metal material. The interface layer may include or be, for example, at least one of metal oxide, metal nitride, metal carbide, and metal silicide.

A first bonding insulation layer 166 may be disposed on the interlayer insulation layer OBL. For example, the first bonding insulation layer 166 may cover and contact a lower surface of the interlayer insulation layer OBL. For example, the first bonding insulation layer 166 may include or be formed of silicon oxide or silicon carbonitride (SiCN).

The peripheral circuit structure PRST may include a peripheral circuit substrate 202 including, on the peripheral circuit substrate 202, a plurality of active regions AC defined by a circuit device isolation layer 204, a plurality of circuit gate structures 210 disposed in the plurality of active regions AC of the peripheral circuit substrate 202, an inter-wiring insulation layer 220 covering the plurality of circuit gate structures 210, and a wiring structure 230 surrounded by the inter-wiring insulation layer 220 and/or electrically connected to the plurality of circuit gate structures 210. The plurality of circuit gate structures 210 respectively disposed in the plurality of active regions AC may form a plurality of peripheral circuit transistors PTR. A second bonding insulation layer 266 may be disposed on the peripheral circuit structure PRST. For example, the second bonding insulation layer 266 may cover the inter-wiring insulation layer 220 and the wiring structure 230. The second bonding insulation layer 266 may include silicon oxide or SiCN. The second bonding insulation layer 266 and the first bonding insulation layer 166 may form a covalent bond and may be bonded to each other. The memory cell array structure MCA and the peripheral circuit structure PRST may be bonded to each other by the first bonding insulation layer 166 and the second bonding insulation layer 266, and the memory cell array structure MCA may be stacked on the peripheral circuit structure PRST.

The peripheral circuit substrate 202 may include, for example, semiconductor materials such as Group IV semiconductor materials, Group III-V semiconductor materials or Group II-VI semiconductor materials, and Group II-VI oxide semiconductor materials. The Group IV semiconductor material may include, for example, Si, Ge, or Si—Ge. The Group III-V semiconductor material may include, for example, gallium arsenide (GaAs), indium phosphide (InP), gallium phosphide (GaP), indium arsenide (InAs), indium antimony (InSb), or indium gallium arsenide (InGaAs). The Group II-VI semiconductor material may include, for example, tellurium zinc (ZnTe) or sulfur cadmium (CdS). The peripheral circuit substrate 202 may be a bulk wafer or an epitaxial layer. The peripheral circuit substrate 202 may also be provided as a bulk wafer or an epitaxial layer. In other embodiments, the peripheral circuit substrate 202 may include a silicon-on-insulator (SOI) substrate or a germanium-on-insulator (GeOI) substrate. The active region AC may be defined by the circuit device isolation layer 204 in the peripheral circuit substrate 202, and the active region AC and the circuit gate structure 210 may form the peripheral circuit transistor PTR.

The circuit gate structure 210 may include a circuit gate electrode 214 on the active region AC, a circuit gate insulation layer 212 disposed between the active region AC and the circuit gate electrode 214, a circuit gate capping layer 216 covering the circuit gate electrode 214, and a circuit gate spacer 218 covering a side surface of each of the circuit gate insulation layer 212, the circuit gate electrode 214, and the circuit gate capping layer 216.

The wiring structure 230 may include a circuit wiring line and a circuit wiring contact. The wiring structure 230 may include a conductive material such as copper (Cu), aluminum (Al), tungsten (W), silver (Ag), gold (Au), or a combination thereof. The inter-wiring insulation layer 220 may include an insulating material which may include silicon oxide, silicon nitride, a low-k dielectric material, or a combination thereof. The low-k dielectric material may be a material having a dielectric constant which is less than that of silicon oxide, and for example, may include phosphosilicate glass (PSG), borophosphosilicate glass (BPSG), fluorosilicate glass (FSG), organosilicate glass (OSG), spin-on-glass (SOG), spin-on-polymer, or a combination thereof. In some embodiments, the inter-wiring insulation layer 220 may include an ultra low k (ULK) layer having an ultra low dielectric constant K of about 2.2 to about 2.4. The ULK layer may include SiOC or SiCOH.

The semiconductor memory device 100 according to an embodiment may include the contact isolation insulation layer 140 surrounding the plurality of contact plugs 130, and the contact isolation insulation layer 140 may include the main isolation insulation layer 142 and the plurality of sub isolation insulation layers 146. Accordingly, the semiconductor memory device 100 may prevent the occurrence of a bridge between the plurality of contact plugs 130, thereby enhancing operation reliability.

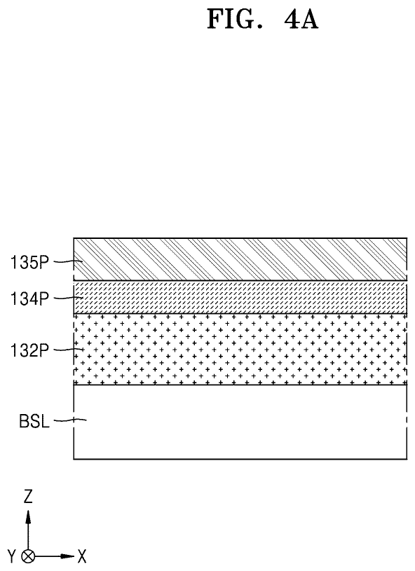

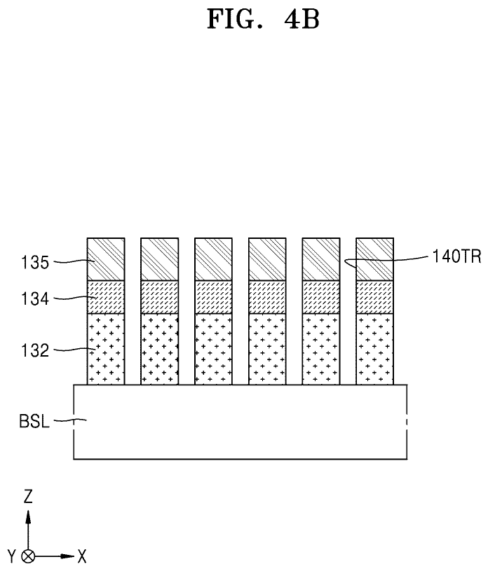

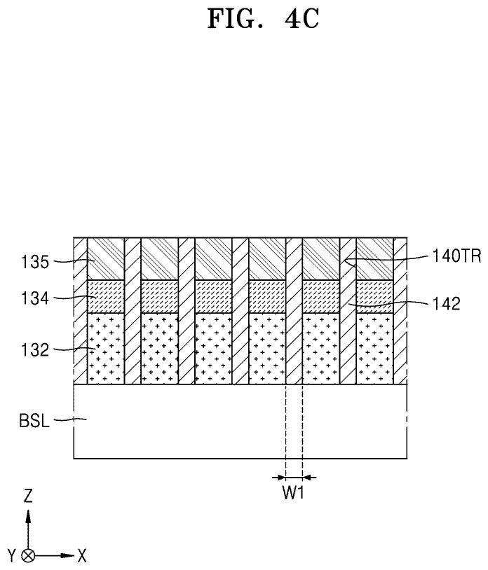

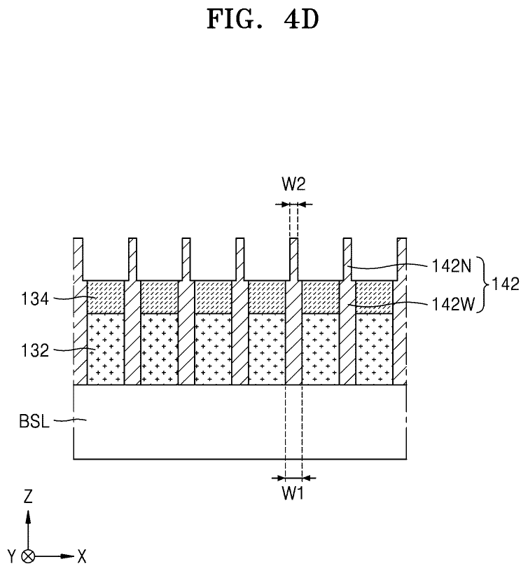

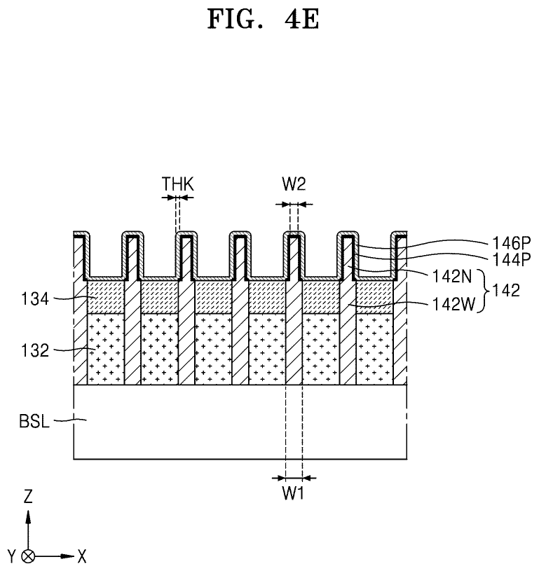

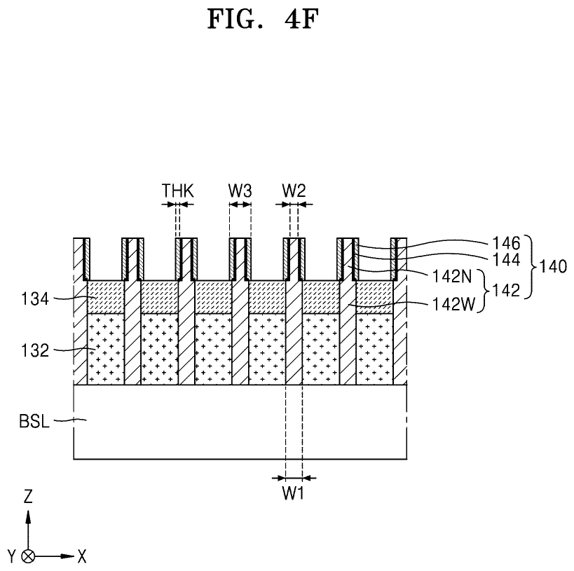

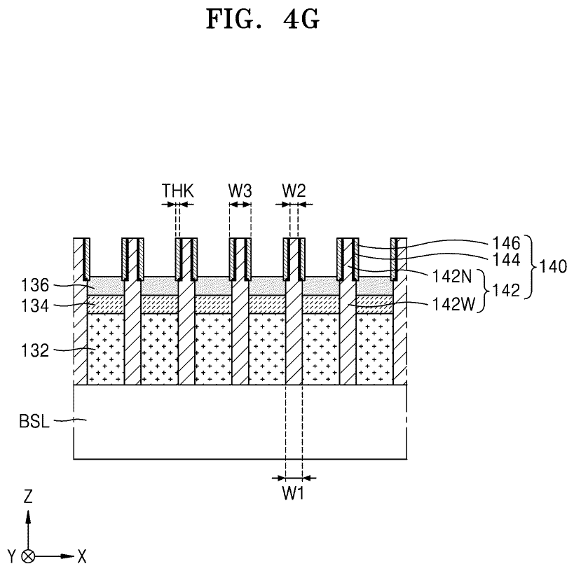

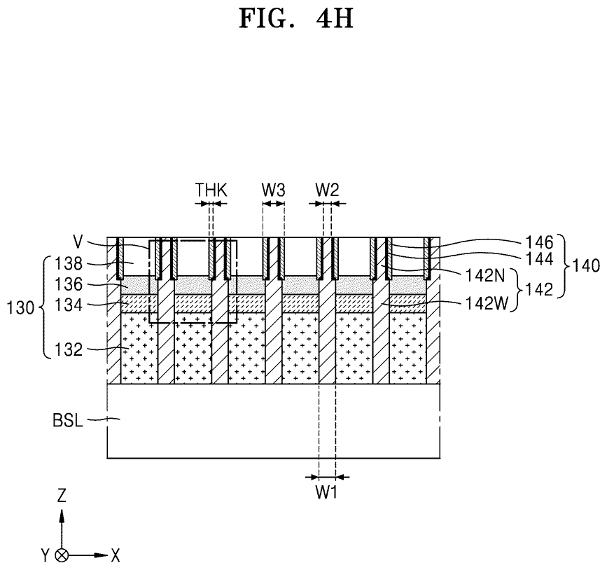

FIGS. 4A to 4H are cross-sectional views for describing a method of manufacturing a semiconductor memory device, according to embodiments. In detail, FIGS. 4A to 4H are cross-sectional views illustrating a method of manufacturing the contact plug 130 and the contact isolation insulation layer 140 illustrated in FIGS. 3A and 3B.

Referring to FIG. 4A, a first conductive layer 132P, a second conductive layer 134P, and a mold insulation layer 135P are sequentially formed on a base layer BSL. The base layer BSL may include the channel structure CHST illustrated in FIG. 3A. In some embodiments, the base layer BSL may include the bit line structure BLST illustrated in FIG. 3A and the channel structure CHST on the bit line structure BLST, but is not limited thereto. For example, the base layer BSL may include the channel structure CHST and may not include the bit line structure BLST. In some embodiments, after the channel structure CHST and the capacitor structure CTST illustrated in FIG. 3A are sequentially formed, a stack structure of the channel structure CHST and the capacitor structure CTST may be vertically reversed, and then, the bit line structure BLST may be formed.

For example, the first conductive layer 132P may include undoped polysilicon, the second conductive layer 134P may include doped polysilicon, and the mold insulation layer 135P may include oxide. For example, the mold insulation layer 135P may include plasma enhanced oxide (PEOX), tetraethyl orthosilicate (TEOS), boro tetraethyl orthosilicate (BTEOS), phosphorous tetraethyl orthosilicate (PTEOS), boro phospho tetraethyl orthosilicate (BPTEOS), boro silicate glass (BSG), phospho silicate glass (PSG), or boro phospho silicate glass (BPSG). In some embodiments, the mold insulation layer 135P may include TEOS.

Referring to FIGS. 4A and 4B, a first conductive pattern 132, a second conductive pattern 134, and a mold insulation pattern 135 are formed by patterning the first conductive layer 132P, the second conductive layer 134P, and the mold insulation layer 135P. An isolation trench 140TR may be formed between a plurality of stack structures where the first conductive pattern 132, the second conductive pattern 134, and the mold insulation pattern 135 are sequentially stacked. The plurality of stack structures where the first conductive pattern 132, the second conductive pattern 134, and the mold insulation pattern 135 are sequentially stacked may be apart from one another in a first horizontal direction (an X direction) and a second horizontal direction (a Y direction) with the isolation trench 140TR therebetween.

Referring to FIG. 4C, a main isolation insulation layer 142 filling the isolation trench 140TR may be formed. The main isolation insulation layer 142 may be formed to have a first horizontal width W1, between stack structures of two first conductive patterns 132, second conductive patterns 134, and mold insulation patterns 135, which are the most adjacent to each other in a horizontal direction. For example, the main isolation insulation layer 142 may be formed to have the first horizontal width W1, between stack structures of two first conductive patterns 132, second conductive patterns 134, and mold insulation patterns 135, which are the most adjacent to each other in the first horizontal direction (the X direction). An upper surface of the main isolation insulation structure 142 and upper surfaces of the plurality of mold insulation patterns 135 may be disposed at the same vertical level to form a coplanar surface.

Referring to FIGS. 4C and 4D, the plurality of mold insulation patterns 135 may be removed. In a process of removing the plurality of mold insulation patterns 135, an upper partial portion of the main isolation insulation layer 142 may be removed, and thus, a horizontal width may be reduced. For example, the main isolation insulation layer 142 may include a first portion 142W and a second portion 142N on the first portion 142W. A horizontal width of the second portion 142N of the main isolation insulation layer 142 may be less than that of the first portion 142W of the main isolation insulation layer 142. The first portion 142W of the main isolation insulation layer 142 may be a portion, buried in the plurality of first conductive patterns 132 and the plurality of second conductive patterns 134, of the main isolation insulation layer 142, and the second portion 142N of the main isolation insulation layer 142 may be a portion, which is exposed as the plurality of mold insulation patterns 135 are removed, of the main isolation insulation layer 142. For example, the first portion 142W of the main isolation insulation layer 142 in the first horizontal direction (the X direction) may have the first horizontal width W1, and the second portion 142N of the main isolation insulation layer 142 may have a second horizontal width W2, which is less than the first horizontal width W1. For example, the first horizontal width W1 may be about 5 nm to about 15 nm, and the second horizontal width W2 may be about 1 nm to about 4 nm less than the first horizontal width W1. For example, the second horizontal width W1 may be between 70% and 80% of the first horizontal width W1.

Referring to FIG. 4E, a preliminary insulation layer 146P conformally covering upper surfaces of the plurality of second conductive patterns 134 and a side surface and an upper surface of the second portion 142N of the main isolation insulation layer 142 may be formed. For example, a thickness THK of the preliminary insulation layer 146P (e.g., in a direction perpendicular to a surface on which it is formed) may be about 0.5 nm to about 4 nm. The thickness THK of the preliminary insulation layer 146P may be greater than or equal to ½ of a difference between the first horizontal width W1 and the second horizontal width W2. In some embodiments, a preliminary interface layer 144P may be formed between the main isolation insulation layer 142 and the preliminary insulation layer 146P.

Referring to FIGS. 4E and 4F, a plurality of sub isolation insulation layers 146 may be formed by removing a portion of the preliminary insulation layer 146P. For example, the plurality of sub isolation insulation layers 146 may be formed by removing portions of the preliminary insulation layer 146P covering the upper surfaces of the plurality of second conductive patterns 134 and the upper surface of the second portion 142N of the main isolation insulation layer 142 through anisotropic etching. The main isolation insulation layer 142 and the plurality of sub isolation insulation layers 146 may form the contact isolation insulation layer 140. In some embodiments, in a process of removing a portion of the preliminary insulation layer 146P, a portion of the preliminary interface layer 144P may be removed together, and thus, a plurality of interface insulation layers 144 may be formed. For example, the contact isolation insulation layer 140 may include the main isolation insulation layer 142, the plurality of sub isolation insulation layers 146, and a plurality of interface insulation layers 144 disposed between the main isolation insulation layer 142 and the plurality of sub isolation insulation layers 146.

The plurality of sub isolation insulation layers 146 may cover side surfaces of the second portion 142N of the main isolation insulation layer 142. For example, the first portion 142W of the main isolation insulation layer 142 in the first horizontal direction (the X direction) may have the first horizontal width W1, the second portion 142N of the main isolation insulation layer 142 may have the second horizontal width W2, which is less than the first horizontal width W1, and the second portion 142N of the main isolation insulation layer 142 and the sub isolation insulation layer 146 covering a side surface of the second portion 142N of the main isolation insulation layer 142 may have a third horizontal width W3, which is greater than or equal to the first horizontal width W1. The third horizontal width W3 may be slightly greater than or equal to the sum of the second horizontal width W2 and two times the thickness THK of the sub isolation insulation layer 146.

Referring to FIGS. 4F and 4G, a plurality of third conductive patterns 136 may be formed on the plurality of second conductive patterns 134. In some embodiments, a metal material layer may be formed on the plurality of second conductive patterns 134, and then, the plurality of third conductive patterns 136 may be formed by performing thermal treatment. For example, each of the plurality of third conductive patterns 136 may include metal silicide.

In some embodiments, the third conductive pattern 136 may be a compound of the metal material layer and an upper partial portion of the second conductive pattern 134. For example, after the plurality of third conductive patterns 136 are formed, upper surfaces of the plurality of second conductive patterns 134 may be disposed at a vertical level which is lower than the upper surfaces of the plurality of second conductive patterns 134 illustrated in FIG. 4F. The lowermost end of each of the plurality of third conductive patterns 136 may be disposed at a vertical level which is lower than the lowermost end of each of the plurality of sub isolation insulation layers 146, and the uppermost end of each of the plurality of third conductive patterns 136 may be disposed at a vertical level which is higher than the lowermost end of each of the plurality of sub isolation insulation layers 146. For example, a lower partial portion of each of the plurality of sub isolation insulation layers 146 may be buried in the plurality of third conductive patterns 136. An upper surface of the main isolation insulation layer 142, upper surfaces of the plurality of sub isolation insulation layers 146, and upper surfaces of the plurality of fourth conductive patterns 138 may form a coplanar surface.

Referring to FIG. 4H, a plurality of fourth conductive patterns 138 may be formed on the plurality of third conductive patterns 136. The plurality of fourth conductive patterns 138 may be formed to fill all of a space limited by the contact isolation insulation layer 140. For example, the space limited by the contact isolation insulation layer 140 (e.g., the spaces formed in and remaining in the contact isolation insulation layer 140) may be fully filled by the plurality of contact plugs 130 formed by the plurality of first conductive patterns 132, the plurality of second conductive patterns 134, the plurality of third conductive patterns 136, and the plurality of fourth conductive patterns 138.

Referring to FIGS. 4A to 4H, as an upper partial portion of the main isolation insulation layer 142 is removed in a process of removing the plurality of mold insulation patterns 135, even when the second portion 142N of the main isolation insulation layer 142 has a horizontal width which is thinner than the first portion 142W, the plurality of sub isolation insulation layers 146 may cover a side surface of the second portion 142N of the main isolation insulation layer 142, and thus, the occurrence of a bridge between the plurality of contact plugs 130 may be prevented, thereby enhancing operation reliability.

FIGS. 5A to 5D are cross-sectional views of a semiconductor memory device according to embodiments. In detail, FIGS. 5A to 5D are enlarged cross-sectional views of an enlarged portion corresponding to a portion V of FIG. 4H.

Referring to FIG. 5A, a contact isolation insulation layer 140 may surround a plurality of contact plugs 130. Each of the plurality of contact plugs 130 may include a first conductive pattern 132, a second conductive pattern 134, a third conductive pattern 136, and a fourth conductive pattern 138, which are sequentially stacked. In some embodiments, a lower surface of the third conductive pattern 136 may have or include a flat surface. A contact isolation insulation layer 140 may fill a space between the plurality of contact plugs 130. The contact isolation insulation layer 140 may include a main isolation insulation layer 142 and a plurality of sub isolation insulation layers 146. The contact isolation insulation layer 140 may further include a plurality of interface insulation layers 144 disposed between the main isolation insulation layer 142 and the plurality of sub isolation insulation layers 146. For example, the plurality of interface insulation layers 144 may form an interface between the main isolation insulation layer 142 and the plurality of sub isolation insulation layers 146.

The main isolation insulation layer 142 may include a first portion 142W and a second portion 142N on the first portion 142W. The first portion 142W of the main isolation insulation layer 142 may be a portion such as a lower portion, facing the channel structure CHST including the plurality of channel patterns CHL illustrated in FIG. 3A, of the main isolation insulation layer 142, and the second portion 142N may be a portion such as an upper portion, facing the plurality of capacitors 150 illustrated in FIG. 3A, of the main isolation insulation layer 142. The first portion 142W of the main isolation insulation layer 142 in a first horizontal direction (an X direction) may have a first horizontal width W1, and the second portion 142N of the main isolation insulation layer 142 may have a second horizontal width W2, which is less than the first horizontal width W1, between contact plugs 130 adjacent to each other in the first horizontal direction (the X direction). The plurality of sub isolation insulation layers 146 may cover side surfaces of the second portion 142N of the main isolation insulation layer 142. For example, the first portion 142W of the main isolation insulation layer 142 in the first horizontal direction (the X direction) may have the first horizontal width W1, and the second portion 142N of the main isolation insulation layer 142 may have the second horizontal width W2, which is less than the first horizontal width W1. The main isolation insulation layer 142 may have a stepped shape between the first portion 142W and the second portion 142N. For example, a portion, which is not covered by the second portion 142N, of an upper end of the first portion 142W may be a stepped-shape tread plate included in the main isolation insulation layer 142, and a side surface of the second portion 142N may be a stepped-shape riser plate included in the main isolation insulation layer 142. The second portion 142N of the main isolation insulation layer 142 and the sub isolation insulation layer 146 covering a side surface of the second portion 142N of the main isolation insulation layer 142 may have a third width W3, which is greater than or equal to the first horizontal width W1. A thickness THK of the plurality of sub isolation insulation layers 146 may be greater than or equal to ½ of a difference between the first horizontal width W1 and the second horizontal width W2. Also, the overall contact isolation insulation layer 140 may have a step shape, in the various embodiments, between an upper portion and a lower portion of the contact isolation insulation layer 140 at an interface or junction where the sub isolation insulation layer 146 ends (e.g., at a vertical height between upper and lower surfaces of the third conductive pattern 136). The step shape may have angled corners or rounded corners. In addition, in various embodiments, a horizontal width (e.g., maximum horizontal width) of each contact plug 130 at a first end of the contact plug connected to the capacitor 150 and located at a first vertical level is smaller than a horizontal width (e.g., maximum horizontal width) of each contact plug 130 at a second end opposite the first end and located at a second vertical level. Furthermore, a minimum horizontal width of the main isolation insulation layer 142 between two adjacent contact plugs 130 at the first vertical level (e.g., a horizontal width in a first horizontal direction where the two adjacent contact plugs 130 are the closest to each other at the first vertical level) is less than a minimum horizontal width of the main isolation insulation layer 142 between the two adjacent contact plugs 130 at the second vertical level (e.g., a horizontal width in the first horizontal direction where the two adjacent contact plugs 130 are the closest to each other at the second vertical level).

The lowermost end of each of the plurality of third conductive patterns 136 may be disposed at a vertical level which is lower than the lowermost end of each of the plurality of sub isolation insulation layers 146, and the uppermost end of each of the plurality of third conductive patterns 136 may be disposed at a vertical level which is higher than the lowermost end of each of the plurality of sub isolation insulation layers 146. For example, a lower partial portion of each of the plurality of sub isolation insulation layers 146 may be buried in the plurality of third conductive patterns 136.

The plurality of interface insulation layers 144 may be disposed between the main isolation insulation layer 142 and the plurality of sub isolation insulation layers 146. For example, the plurality of interface insulation layers 144 may cover a stepped-shape tread plate and riser plate included in the main isolation insulation layer 142, namely, a portion, which is not covered by the second portion 142N, of an upper end of the first portion 142W and a side surface of the second portion 142N.

When each of the plurality of contact plugs 130 has a circular horizontal shape (when viewed from a plan view), each of the sub isolation insulation layers 146 may have a ring-shaped horizontal shape. A portion of a lower surface of each of the plurality of the combined sub isolation insulation layers 146 and interface insulation layers 144 (or a portion of a lower surface of the sub isolation insulation layer 146 when the interface insulation layers 144 are not used) may be adjacent to and may contact a portion of a stepped-shape tread plate included in the main isolation insulation layer 142, namely, the upper end of the first portion 142W of the main isolation insulation layer 142, and the other portion thereof may be adjacent to and may contact the plurality of third conductive patterns 136. An inner surface of each of the plurality of the combined sub isolation insulation layers 146 and interface insulation layers 144 (or an inner surface of the sub isolation insulation layer 146 when the interface insulation layers 144 are not used) having a ring-shaped horizontal shape may cover a stepped-shape riser plate included in the main isolation insulation layer 142, namely, a side surface of the second portion 142N of the main isolation insulation layer 142, and moreover, an upper portion of an outer surface of each of the plurality of sub isolation insulation layers 146 may be adjacent to and may contact the plurality of fourth conductive patterns 138, and a lower portion thereof may be adjacent to and may contact the plurality of third conductive patterns 136.

Referring to FIG. 5B, the contact isolation insulation layer 140 may surround a plurality of contact plugs 130a. Each of the plurality of contact plugs 130a may include a first conductive pattern 132, a second conductive pattern 134a, a third conductive pattern 136a, and a fourth conductive pattern 138, which are sequentially stacked. In some embodiments, a lower surface of the third conductive pattern 136a may include a convex surface toward the second conductive pattern 134a, and an upper surface of the second conductive pattern 134a may include a concave surface corresponding to a lower surface of the third conductive pattern 136a toward the third conductive pattern 136a. The contact isolation insulation layer 140 may fill a space between the plurality of contact plugs 130a. The contact isolation insulation layer 140 may include a main isolation insulation layer 142 and a plurality of sub isolation insulation layers 146. The contact isolation insulation layer 140 may further include a plurality of interface insulation layers 144 disposed between the main isolation insulation layer 142 and the plurality of sub isolation insulation layers 146.

Referring to FIG. 5C, a contact isolation insulation layer 140a may surround a plurality of contact plugs 130. Each of the plurality of contact plugs 130 may include a first conductive pattern 132, a second conductive pattern 134, a third conductive pattern 136, and a fourth conductive pattern 138, which are sequentially stacked. A contact isolation insulation layer 140a may fill a space between the plurality of contact plugs 130. The contact isolation insulation layer 140a may include a main isolation insulation layer 142a and a plurality of sub isolation insulation layers 146a. The plurality of sub isolation insulation layers 146a may contact the main isolation insulation layer 142a. For example, an interface may be provided between the main isolation insulation layer 142a and the plurality of sub isolation insulation layers 146a, but a component (for example, oxygen) where a thickness is physically observed or which chemically differs may not be detected. In this embodiment, an interface isolation insulation layer such as depicted in FIGS. 5A and 5B is not included.

Referring to FIG. 5D, a contact isolation insulation layer 140b may surround a plurality of contact plugs 130. Each of the plurality of contact plugs 130 may include a first conductive pattern 132, a second conductive pattern 134, a third conductive pattern 136, and a fourth conductive pattern 138, which are sequentially stacked. A contact isolation insulation layer 140b may fill a space between the plurality of contact plugs 130. The contact isolation insulation layer 140b may include a main isolation insulation layer 142b and a plurality of sub isolation insulation layers 146b. The contact isolation insulation layer 140b may further include a plurality of interface insulation layers 144b disposed between the main isolation insulation layer 142b and the plurality of sub isolation insulation layers 146b. For example, the plurality of interface insulation layers 144b may form an interface between the main isolation insulation layer 142b and the plurality of sub isolation insulation layers 146b. In some embodiments, the plurality of sub isolation insulation layers 146b do not overlap the main isolation insulation layer 142b in a vertical direction (a Z direction).

The main isolation insulation layer 142b may include a first portion 142L and a second portion 142U on the first portion 142L. The first portion 142L of the main isolation insulation layer 142b may be a portion, facing the channel structure CHST including the plurality of channel patterns CHL illustrated in FIG. 3A, of the main isolation insulation layer 142b, and the second portion 142U may be a portion, facing the plurality of capacitors 150 illustrated in FIG. 3A, of the main isolation insulation layer 142b. The first portion 142L of the main isolation insulation layer 142b in a first horizontal direction (an X direction) may have a first horizontal width W1a, and the second portion 142U of the main isolation insulation layer 142b may have a second horizontal width W2a, between contact plugs 130 adjacent to each other in the first horizontal direction (the X direction). The first horizontal width W1a and the second horizontal width W2a may have the same value. The plurality of sub isolation insulation layers 146b may cover side surfaces of the second portion 142U of the main isolation insulation layer 142b. The main isolation insulation layer 142b may include a side surface which extends in the vertical direction (the Z direction). For example, a side surface of the first portion 142L and a side surface of the second portion 142U may be aligned in the vertical direction (the Z direction). The contact isolation insulation layer 140b may include a lower portion formed of the first portion 142L of the main isolation insulation layer 142b and an upper portion formed of the second portion 142U of the main isolation insulation layer 142b, the interface insulation layer 144b, and the sub isolation insulation layer 146b. In some embodiments, the upper portion of the contact isolation insulation layer 140b may be configured to include the second portion 142U of the main isolation insulation layer 142b, the sub isolation insulation layer 146b, and the interface insulation layer 144b. A lower portion of the contact isolation insulation layer 140b may have the first horizontal width W1a, and an upper portion of the contact isolation insulation layer 140b may have a third horizontal width W3a which is greater than the first horizontal width W1a.

The lowermost end of each of the plurality of third conductive patterns 136 may be disposed at a vertical level which is lower than the lowermost end of each of the plurality of sub isolation insulation layers 146b, and the uppermost end of each of the plurality of third conductive patterns 136 may be disposed at a vertical level which is higher than the lowermost end of each of the plurality of sub isolation insulation layers 146b. For example, a lower partial portion of each of the plurality of sub isolation insulation layers 146b may be buried in the plurality of third conductive patterns 136. For example, a boundary between the upper portion of the contact isolation insulation layer 140b having the third horizontal width W3a and the lower portion of the contact isolation insulation layer 140b having the first horizontal width W1a may be disposed at a vertical level which is lower than an upper surface of the third conductive pattern 136 and higher than a lower surface of the third conductive pattern 136. The alternate features for the contact plug shown in FIG. 5A may be used with any of the embodiments of FIGS. 5B to 5D.

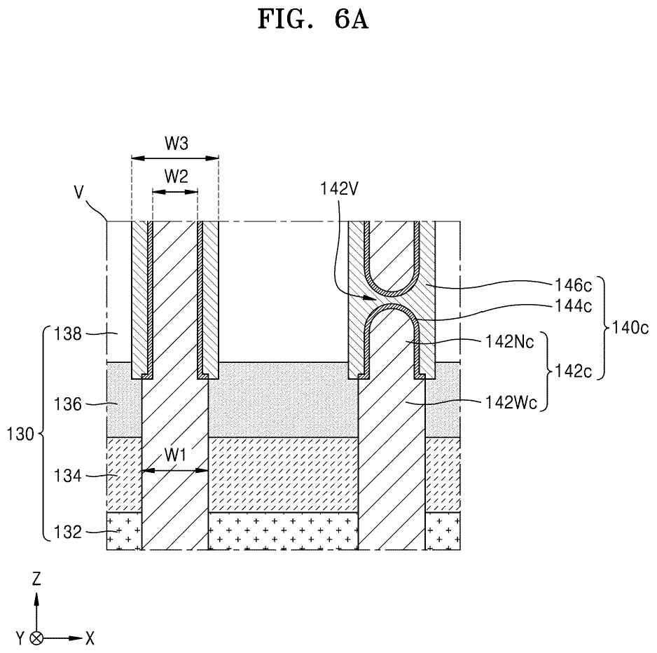

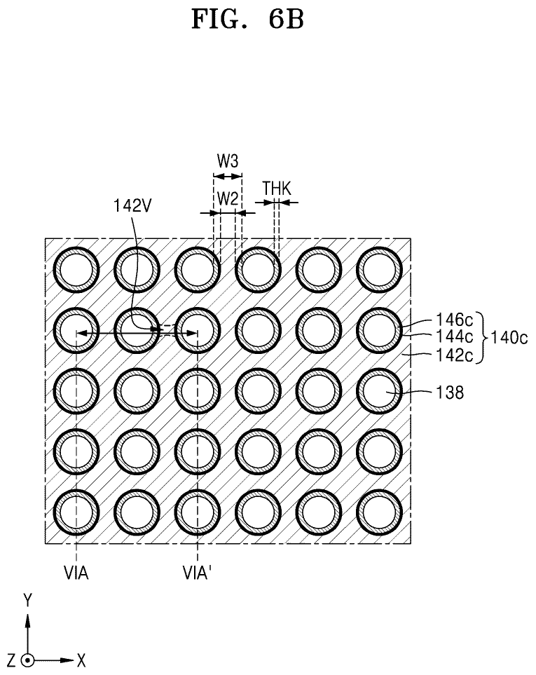

FIGS. 6A and 6B are a cross-sectional view and a plan view of a semiconductor memory device according to embodiments. In detail, FIG. 6A is an enlarged cross-sectional view of an enlarged portion corresponding to a portion V of FIG. 4H, FIG. 6A is a cross-sectional view taken along line VIA-VIA′ of FIG. 6B, and FIG. 6B is a plan view illustrating a fourth conductive pattern 138 and a contact isolation insulation layer 140c illustrated in FIG. 6A.

Referring to FIGS. 6A and 6B, a contact isolation insulation layer 140c may surround a plurality of contact plugs 130. Each of the plurality of contact plugs 130 may include a first conductive pattern 132, a second conductive pattern 134, a third conductive pattern 136, and a fourth conductive pattern 138, which are sequentially stacked. A contact isolation insulation layer 140c may fill a space between the plurality of contact plugs 130. The contact isolation insulation layer 140c may include a main isolation insulation layer 142c, a plurality of sub isolation insulation layers 146c, and a plurality of interface insulation layers 144c disposed between the main isolation insulation layer 142c and the plurality of sub isolation insulation layers 146c. In some embodiments, the contact isolation insulation layer 140c may not include the plurality of interface insulation layers 144c.

In some embodiments, a first portion 142Wc, which is a lower portion, of the main isolation insulation layer 142c may have a first horizontal width W1, and a second portion 142Nc, which is an upper portion, of the main isolation insulation layer 142c may have a second horizontal width W2, which is less than the first horizontal width W1. The sub isolation insulation layer 146c may have a certain thickness THK and may cover the second portion 142Nc of the main isolation insulation layer 142c. A lower portion of the contact isolation insulation layer 140c may have the first horizontal width W1, and an upper portion of the contact isolation insulation layer 140 may have a third horizontal width W3, which is greater than the first horizontal width W1.

The main isolation insulation layer 142c may include a first portion 142Wc and a second portion 142Nc on the first portion 142Wc. In some embodiments, the main isolation insulation layer 142c may include at least one void 142V in the second portion 142Nc. The at least one void 142V included in the second portion 142Nc of the main isolation insulation layer 142c may be formed when an upper partial portion of the main isolation insulation layer 142 is removed together, in a process of removing the plurality of mold insulation patterns 135 illustrated in FIGS. 4C and 4D. The plurality of sub isolation insulation layers 146c may cover side surfaces of the second portion 142Nc of the main isolation insulation layer 142c and may fill the at least one void 142V included in the second portion 142Nc of the main isolation insulation layer 142c.

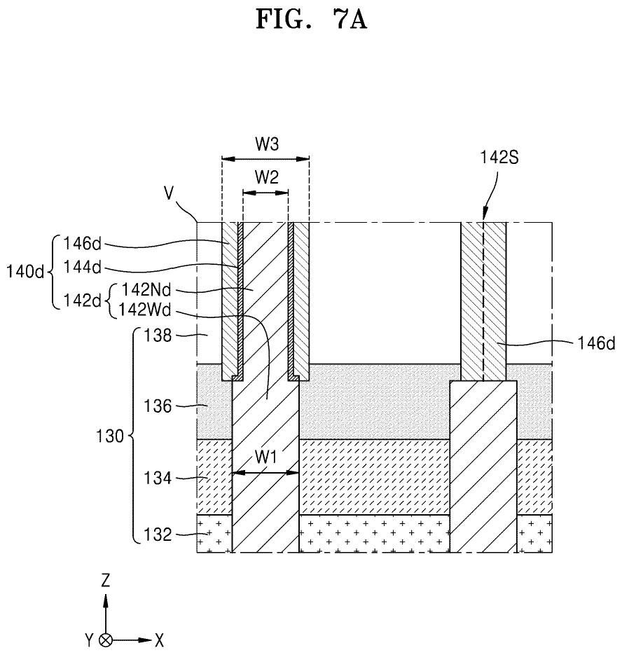

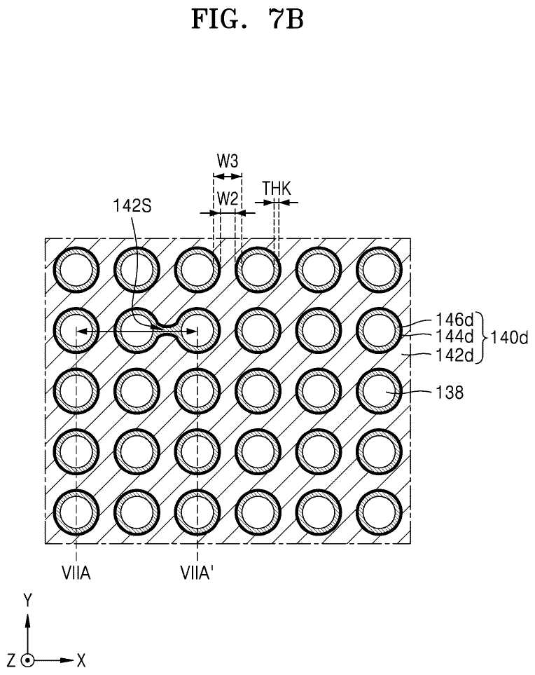

FIGS. 7A and 7B are a cross-sectional view and a plan view of a semiconductor memory device according to embodiments. In detail, FIG. 7A is an enlarged cross-sectional view of an enlarged portion corresponding to the portion V of FIG. 4H, FIG. 7A is a cross-sectional view taken along line VIIA-VIIA′ of FIG. 7B, and FIG. 7B is a plan view illustrating a fourth conductive pattern 138 and a contact isolation insulation layer 140d illustrated in FIG. 7A.

Referring to FIGS. 7A and 7B, a contact isolation insulation layer 140d may surround a plurality of contact plugs 130. Each of the plurality of contact plugs 130 may include a first conductive pattern 132, a second conductive pattern 134, a third conductive pattern 136, and a fourth conductive pattern 138, which are sequentially stacked. A contact isolation insulation layer 140d may fill a space between the plurality of contact plugs 130. The contact isolation insulation layer 140d may include a main isolation insulation layer 142d, a plurality of sub isolation insulation layers 146d, and a plurality of interface insulation layers 144d disposed between the main isolation insulation layer 142d and the plurality of sub isolation insulation layers 146d. In some embodiments, the contact isolation insulation layer 140d may not include the plurality of interface insulation layers 144d.

In some embodiments, a first portion 142Wd, which is a lower portion, of the main isolation insulation layer 142d may have a first horizontal width W1, and a second portion 142Nd, which is an upper portion, of the main isolation insulation layer 142d may have a second horizontal width W2, which is less than the first horizontal width W1. The sub isolation insulation layer 146d may have a certain thickness THK and may cover the second portion 142Nd of the main isolation insulation layer 142d. A lower portion of the contact isolation insulation layer 140d may have the first horizontal width W1, and an upper portion of the contact isolation insulation layer 140 may have a third horizontal width W3, which is greater than the first horizontal width W1.

The main isolation insulation layer 142d may include a first portion 142Wd and a second portion 142Nd on the first portion 142Wd. In some embodiments, the main isolation insulation layer 142d may include at least one slit 142S in the second portion 142Nd. The at least one slit 142S included in the second portion 142Nd of the main isolation insulation layer 142d may be formed when an upper partial portion of the main isolation insulation layer 142 is removed together, in a process of removing the plurality of mold insulation patterns 135 illustrated in FIGS. 4C and 4D. The at least one slit 142S included in the second portion 142Nd of the main isolation insulation layer 142d may extend in the vertical direction (the Z direction). In some embodiments, the at least one slit 142S included in the second portion 142Nd of the main isolation insulation layer 142d may extend in the vertical direction (the Z direction) up to the lowermost end of the second portion 142Nd from the uppermost end of the second portion 142Nd, but is not limited thereto. For example, the at least one slit 142S included in the second portion 142Nd of the main isolation insulation layer 142d may extend in the vertical direction (the Z direction) toward the lowermost end of the second portion 142Nd from the uppermost end of the second portion 142Nd and may not extend up to the lowermost end of the second portion 142Nd. For example, the at least one slit 142S included in the second portion 142Nd of the main isolation insulation layer 142d may extend in the vertical direction (the Z direction) toward the uppermost end of the second portion 142Nd from the lowermost end of the second portion 142Nd and may not extend up to the uppermost end of the second portion 142Nd. For example, the at least one slit 142S included in the second portion 142Nd of the main isolation insulation layer 142d may extend in the vertical direction (the Z direction) up to a vertical level, which is higher than the lowermost end of the second portion 142Nd, from a vertical level which is lower than the uppermost end of the second portion 142Nd. The plurality of sub isolation insulation layers 146d may cover side surfaces of the second portion 142Nd of the main isolation insulation layer 142d and may fill the at least one slit 142S included in the second portion 142Nd of the main isolation insulation layer 142d.

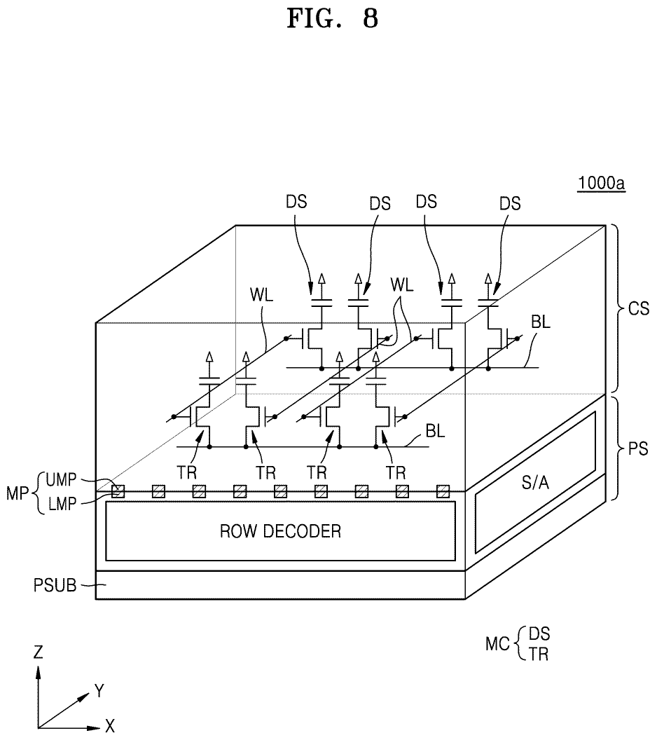

FIG. 8 is a perspective view schematically illustrating a semiconductor memory device 1000a according to embodiments.

Referring to FIG. 8, the semiconductor memory device 1000a may include a peripheral circuit structure PS including a peripheral circuit substrate PSUB and a cell array structure CS on the peripheral circuit structure PS. The peripheral circuit substrate PSUB, the peripheral circuit structure PS, and the cell array structure CS illustrated in FIG. 8 may be substantially the same as the peripheral circuit substrate PSUB, the peripheral circuit structure PS, and the cell array structure CS illustrated in FIG. 2, and thus, repeated descriptions may be omitted.

The cell array structure CS may be bonded to the peripheral circuit structure PS. Lower metal pads LMP may be disposed in an uppermost layer of the peripheral circuit structure PS. The lower metal pads LMP may be electrically connected to a core and peripheral circuits included in the peripheral circuit structure PS. Upper metal pads UMP may be disposed in a lowermost layer of the cell array structure CS. The upper metal pads UMP may be electrically connected to a memory cell array (1010 of FIG. 1) included in the cell array structure CS. The upper metal pads UMP may contact and be bonded to the lower metal pads LMP of the peripheral circuit structure PS. In some embodiments, the peripheral circuit structure PS and the cell array structure CS may be bonded to each other by a metal-oxide hybrid bonding process, and thus, the memory cell array (1010 of FIG. 1) included in the cell array structure CS may be electrically connected to the core and the peripheral circuits each included in the peripheral circuit structure PS. For example, the lower metal pads LMP and the upper metal pads UMP corresponding to each other may expand based on heat and may be bonded to each other, and then, may be a plurality of bonding pads MP which are diffusion-bonded to each other to form one body through diffusion of metal atoms, and an insulation layer surrounding the lower metal pads LMP included in the peripheral circuit structure PS and an insulation layer surrounding the upper metal pads UMP included in the cell array structure CS may form a covalent bond and may be bonded to each other.

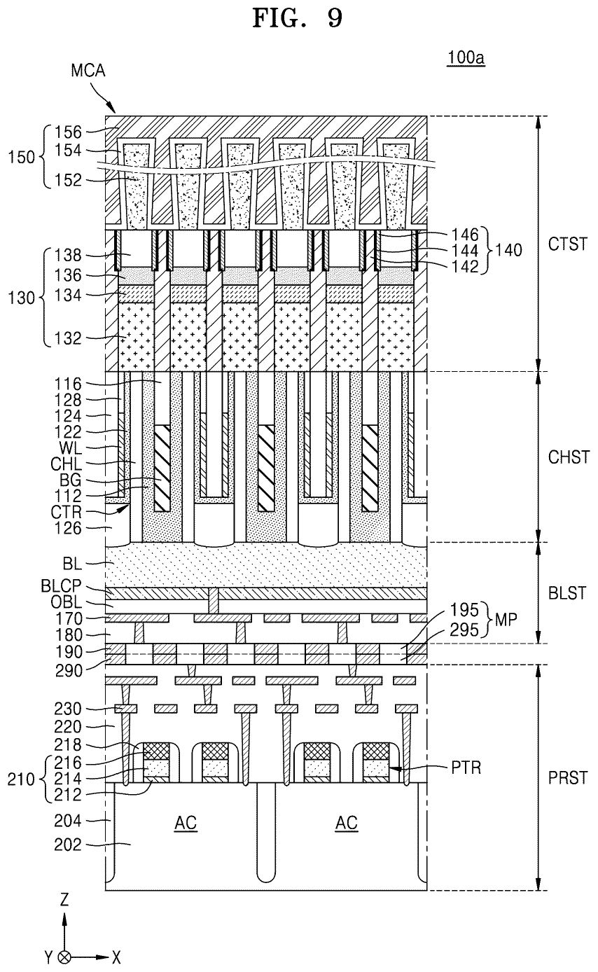

FIG. 9 is a cross-sectional view illustrating a semiconductor memory device 100a according to embodiments.

Referring to FIG. 9, the semiconductor memory device 100a may include a memory cell array structure MCA where a plurality of memory cells are disposed. For example, the plurality of memory cells may include a plurality of vertical channel transistors CTR. The memory cell structure MCA may be configured by stacking a bit line structure BLST, a channel structure CHST, and a capacitor structure CTST. A peripheral circuit structure PRST may include a peripheral circuit transistor PTR configured by a circuit gate structure 210. In some embodiments, the semiconductor memory device 100a may have a CoP structure where the memory cell array structure MCA and the peripheral circuit structure PRST overlap each other in a vertical direction (a Z direction). The peripheral circuit structure PRST, the bit line structure BLST, the channel structure CHST, and the capacitor structure CTST illustrated in FIG. 9 may be substantially the same as the peripheral circuit structure PRST, the bit line structure BLST, the channel structure CHST, and the capacitor structure CTST illustrated in FIG. 3A, and thus, repeated descriptions may be omitted.

The bit line structure BLST may further include a cell wiring structure 170 disposed under an interlayer insulation layer OBL and a cell inter-wiring insulation layer 180 surrounding the cell wiring structure 170. The cell wiring structure 170 may include a plurality of cell wiring lines and a plurality of cell wiring contacts. The cell wiring structure 170 may include a conductive material such as Cu, Al, W, Ag, Au, or a combination thereof. The cell inter-wiring insulation layer 180 may include an insulating material which may include silicon oxide, silicon nitride, a low-k dielectric material, or a combination thereof. Some of the plurality of cell wiring contacts of the cell wiring structure 170 may pass through the interlayer insulation layer OBL and at least some of a plurality of insulation capping lines BLCP and may electrically connect at least some of a plurality of bit lines BL to at least some of the plurality of cell wiring lines.

A plurality of upper metal pads 195 electrically connected to the cell wiring structure 170 and a first bonding insulation layer 190 surrounding the plurality of upper metal pads 195 may be disposed under the cell wiring structure 170 and the cell inter-wiring insulation layer 180. A plurality of lower metal pads 295 electrically connected to the wiring structure 230 and a second bonding insulation layer 290 surrounding the plurality of lower metal pads 295 may be disposed on the inter-wiring insulation layer 220 and the wiring structure 230. Each of the first bonding insulation layer 190 and the second bonding insulation layer 290 may include silicon oxide or SiCN. In some embodiments, the peripheral circuit structure PRST and the memory cell array structure MCA may be bonded to each other by a metal-oxide hybrid bonding process. The first bonding insulation layer 190 and the second bonding insulation layer 290 may contact each other to form a covalent bond and may be bonded to each other. The plurality of upper metal pads 195 and the plurality of lower metal pads 295 corresponding to each other may expand based on heat and may be bonded to each other, and then, may be a plurality of bonding pads MP which are diffusion-bonded to each other to form one body through diffusion of metal atoms. The upper metal pad 195 and the lower metal pad 295 may be the upper metal pad UMP and the lower metal pad LMP illustrated in FIG. 8.

FIG. 10 is a cross-sectional view illustrating a semiconductor memory device 100b according to embodiments.

Referring to FIG. 10, the semiconductor memory device 100b may include a memory cell array structure MCA where a plurality of memory cells are disposed. In some embodiments, the semiconductor memory device 100b may have a CoP structure where the memory cell array structure MCA and the peripheral circuit structure PRST overlap each other in a vertical direction (a Z direction). In the semiconductor memory device 100b, a memory cell array structure MCA may be stacked on a peripheral circuit structure PRST, and the memory cell array structure MCA may include a capacitor structure CTST, a channel structure CHST, and a bit line structure BLST, which are sequentially stacked on the peripheral circuit structure PLST. The peripheral circuit structure PRST, the bit line structure BLST, the channel structure CHST, and the capacitor structure CTST illustrated in FIG. 10 may be substantially the same as the peripheral circuit structure PRST, the bit line structure BLST, the channel structure CHST, and the capacitor structure CTST illustrated in FIG. 3A but may have a vertically reversed structure, and thus, repeated descriptions may be omitted.

The capacitor structure CTST may include a plurality of contact plugs 130, a contact isolation insulation layer 140 surrounding the plurality of contact plugs 130, a plurality of lower electrodes 152 respectively connected to lower portions of the plurality of contact plugs 130, a capacitor dielectric layer 154 conformally covering a surface of each of the plurality of lower electrodes 152, and a plurality of capacitors 150 including an upper electrode 156 covering lower portions of the plurality of lower electrodes 152 with the capacitor dielectric layer 154 therebetween. In some embodiments, the capacitor structure CTST may further include a capacitor capping layer CTCP covering a lower surface of the upper electrode 156. The capacitor capping layer CTCP may include silicon oxide, silicon nitride, or a combination thereof.

The bit line structure BLST may include a plurality of bit lines BL, a plurality of insulation capping lines BLCP respectively covering upper surfaces of the plurality of bit lines BL, and an interlayer insulation layer OBL surrounding the plurality of bit lines BL and the plurality of insulation capping lines BLCP. In some embodiments, the bit line structure BLST may further include a bit line capping layer CBL covering an upper surface of the interlayer insulation layer OBL. The bit line capping layer CBL may include silicon nitride. The bit lines BL and word lines WL may connect to the wiring structure 230 of the peripheral circuit structure PRST in a region outside of the memory cell array structure MCA, for example through conductive vias.

In some embodiments, a first bonding insulation layer 166 may be disposed on the capacitor capping layer CTCP. For example, the first bonding insulation layer 166 may cover a lower surface of the capacitor capping layer CTCP. The second bonding insulation layer 266 may cover an inter-wiring insulation layer 220 and a wiring structure 230. The second bonding insulation layer 266 and the first bonding insulation layer 166 may form a covalent bond and may be bonded to each other. The memory cell array structure MCA and the peripheral circuit structure PRST may be bonded to each other by the first bonding insulation layer 166 and the second bonding insulation layer 266, and the memory cell array structure MCA may be stacked on the peripheral circuit structure PRST.

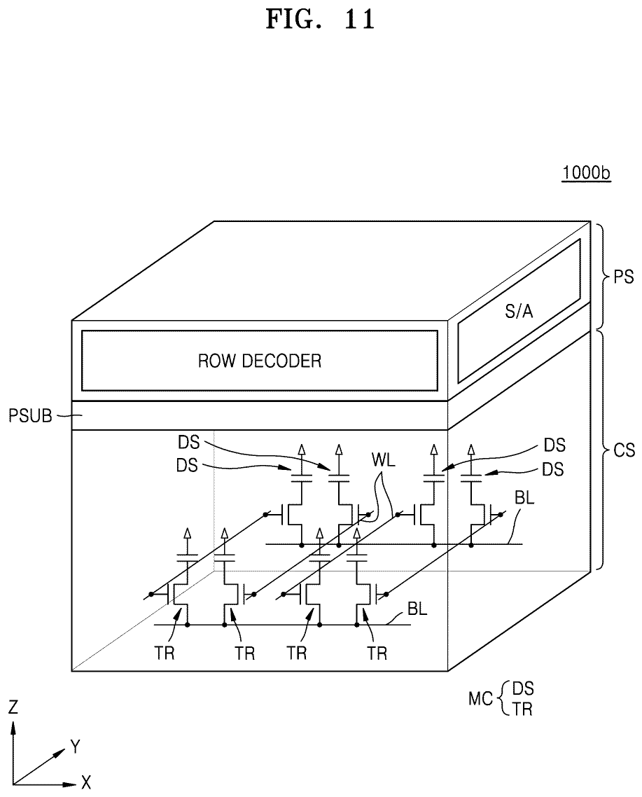

FIG. 11 is a perspective view schematically illustrating a semiconductor memory device 1000b according to embodiments.

Referring to FIG. 11, the semiconductor memory device 1000b may include a cell array structure CS and a peripheral circuit structure PS on the cell array structure CS. The peripheral circuit substrate PSUB, the peripheral circuit structure PS, and the cell array structure CS illustrated in FIG. 11 may be substantially the same as the peripheral circuit substrate PSUB, the peripheral circuit structure PS, and the cell array structure CS illustrated in FIG. 2, and thus, repeated descriptions may be omitted.

The peripheral circuit structure PS may be bonded to the cell array structure CS. In FIG. 11, it is illustrated that the peripheral circuit substrate PSUB is disposed at a side facing the cell array structure CS in a vertical direction (a Z direction) in the peripheral circuit structure PS, but the inventive concept is not limited thereto. In some embodiments, the peripheral circuit substrate PSUB may be disposed at a side opposite to the cell array structure CS in the vertical direction (the Z direction) in the peripheral circuit structure PS.

In some embodiments, in the semiconductor memory device 1000b, the peripheral circuit structure PS and the cell array structure CS may be bonded to each other by a metal-oxide hybrid bonding process, like the semiconductor memory device 1000a illustrated in FIG. 8.

FIGS. 12A and 12B are cross-sectional views illustrating a semiconductor memory device according to embodiments.

Referring to FIG. 12A, a semiconductor memory device 100c may include a memory cell array structure MCA where a plurality of memory cells are disposed and a peripheral circuit structure PRST which is stacked on the memory cell array structure MCA. In some embodiments, the semiconductor memory device 100c may have a PoC structure where the peripheral circuit structure PRST and the memory cell array structure MCA overlap each other in a vertical direction (a Z direction). The peripheral circuit structure PRST, the bit line structure BLST, the channel structure CHST, and the capacitor structure CTST illustrated in FIG. 12A may be substantially the same as the peripheral circuit structure PRST, the bit line structure BLST, the channel structure CHST, and the capacitor structure CTST illustrated in FIG. 3A, and thus, repeated descriptions may be omitted.

The capacitor structure CTST may further include a capacitor capping layer CTCP covering an upper surface of the upper electrode 156. The peripheral circuit structure PRST may further include a peripheral circuit capping layer PRCP covering an inter-wiring insulation layer 220 and a wiring structure 230. Each of the capacitor capping layer CTCP and the peripheral circuit capping layer PRCP may include silicon oxide, silicon nitride, or a combination thereof.

In some embodiments, a first bonding insulation layer 166 may be disposed on the capacitor capping layer CTCP. For example, the first bonding insulation layer 166 may cover an upper surface of the capacitor capping layer CTCP. A second bonding insulation layer 266 may cover a lower surface of the peripheral circuit structure PRST. In some embodiments, the second bonding insulation layer 266 may cover a lower surface of a peripheral circuit substrate 202. The second bonding insulation layer 266 and the first bonding insulation layer 166 may form a covalent bond and may be bonded to each other. The memory cell array structure MCA and the peripheral circuit structure PRST may be bonded to each other by the first bonding insulation layer 166 and the second bonding insulation layer 266, and the peripheral circuit structure PRST may be stacked on the memory cell array structure MCA.

Referring to FIG. 12B, a semiconductor memory device 100d may include a memory cell array structure MCA where a plurality of memory cells are disposed and a peripheral circuit structure PRST which is stacked on the memory cell array structure MCA. In some embodiments, the semiconductor memory device 100d may have a PoC structure where the peripheral circuit structure PRST and the memory cell array structure MCA overlap each other in a vertical direction (a Z direction). The peripheral circuit structure PRST, the bit line structure BLST, the channel structure CHST, and the capacitor structure CTST illustrated in FIG. 12B may be substantially the same as the peripheral circuit structure PRST, the bit line structure BLST, the channel structure CHST, and the capacitor structure CTST illustrated in FIG. 10, and thus, repeated descriptions may be omitted.

The capacitor structure CTST may be attached to a supporting substrate 102. The supporting substrate 102 may include, for example, semiconductor materials such as Group IV semiconductor materials, Group III-V semiconductor materials or Group II-VI semiconductor materials, and Group II-VI oxide semiconductor materials. The capacitor structure CTST may further include a capacitor capping layer CTCP covering a lower surface of the upper electrode 156. In some embodiments, the capacitor capping layer CTCP may perform a function of a bonding insulation layer for bonding the supporting substrate 102 to the capacitor structure CTST. For example, after the capacitor structure CTST is formed, the capacitor structure CTST may be attached to the supporting substrate 102 so that the capacitor capping layer CTCP of the capacitor structure CTST faces the supporting substrate 102. For example, the capacitor capping layer CTCP may include silicon oxide, silicon nitride, or a combination thereof.

The peripheral circuit structure PRST may further include a peripheral circuit capping layer PRCP covering an inter-wiring insulation layer 220 and a wiring structure 230. Each of the capacitor capping layer CTCP and the peripheral circuit capping layer PRCP may include silicon oxide, silicon nitride, or a combination thereof.

A first bonding insulation layer 166 may be disposed on the interlayer insulation layer OBL. For example, the first bonding insulation layer 166 may cover an upper surface of the interlayer insulation layer OBL. A second bonding insulation layer 266 may cover a lower surface of the peripheral circuit structure PRST. In some embodiments, the second bonding insulation layer 266 may cover a lower surface of a peripheral circuit substrate 202. The second bonding insulation layer 266 and the first bonding insulation layer 166 may configure a covalent bond and may be bonded to each other. The memory cell array structure MCA and the peripheral circuit structure PRST may be bonded to each other by the first bonding insulation layer 166 and the second bonding insulation layer 266, and the peripheral circuit structure PRST may be stacked on the memory cell array structure MCA. The bit lines BL and word lines WL in FIGS. 12A and 12B may connect to the wiring structure 230 of the peripheral circuit structure PRST in a region outside of the memory cell array structure MCA, for example through conductive vias.

Hereinabove, exemplary embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept.

While the inventive concept has been particularly shown and described with reference to embodiments thereof, it will be understood that various changes in form and details may be made therein without departing from the spirit and scope of the following claims.

What is claimed is:

1. A semiconductor memory device comprising:
a bit line extending in a horizontal direction;
a contact plug;
a contact isolation insulation layer surrounding the contact plug, the contact isolation insulation layer including a main isolation insulation layer and a sub isolation insulation layer, the sub isolation insulation layer disposed between a portion of the contact plug and the main isolation insulation layer, wherein a step shape is formed in the contact isolation insulation layer between an upper portion of the contact isolation insulation layer and a lower portion of the contact isolation insulation layer;
a channel pattern disposed between the bit line and the contact plug and extending in a vertical direction; and
a capacitor connected to the contact plug.

2. The semiconductor memory device of claim 1, wherein:
the main isolation insulation layer comprises a first portion adjacent to the channel pattern and having a first horizontal width and a second portion on the first portion to overlap the first portion along the vertical direction, and adjacent to the capacitor, the second portion having a second horizontal width which is less than the first horizontal width, and
the sub isolation insulation layer covers a side surface of the second portion of the main isolation insulation layer.

3. The semiconductor memory device of claim 2, wherein a thickness of the sub isolation insulation layer is greater than or equal to ½ of a difference between the first horizontal width and the second horizontal width.

4. The semiconductor memory device of claim 2, wherein the contact plug comprises a semiconductor pattern connected to and adjacent to the bit line, a metal pattern connected to and adjacent to the capacitor, and a metal silicide pattern disposed between the semiconductor pattern and the metal pattern.

5. The semiconductor memory device of claim 4, wherein, with respect to the vertical direction, a first end surface of the sub isolation insulation layer is disposed at the same vertical level as a first end surface of the main isolation insulation layer, and a second, opposite end surface of the sub isolation insulation layer is disposed at a vertical level between a first end and a second, opposite end of the metal silicide pattern.

6. The semiconductor memory device of claim 4, wherein the main isolation insulation layer has a stepped shape between the first portion and the second portion, and
a portion of a lower surface of the sub isolation insulation layer is adjacent to a portion of a stepped-shape tread plate included in the main isolation insulation layer, and another portion of the sub isolation insulation layer is adjacent to the metal silicide pattern.

7. The semiconductor memory device of claim 2, wherein the second portion of the main isolation insulation layer comprises at least one void, and
the sub isolation insulation layer fills the at least one void.

8. The semiconductor memory device of claim 1, wherein the contact isolation insulation layer further comprises an interface insulation layer disposed between the main isolation insulation layer and the sub isolation insulation layer.

9. The semiconductor memory device of claim 1, wherein the sub isolation insulation layer has a ring shaped when viewed from a plan view and surrounds a portion of the contact plug.

10. The semiconductor memory device of claim 1, wherein:
the contact plug is one of a plurality of contact plugs, and the capacitor is one of a plurality of capacitors respectively connected to the plurality of contact plugs;
a horizontal width of each contact plug at a first end of the contact plug connected to the capacitor and located at a first vertical level is smaller than a horizontal width of each contact plug at a second end opposite the first end and located at a second vertical level; and
a minimum horizontal width of the main isolation insulation layer between two adjacent contact plugs at the first vertical level is greater than a minimum horizontal width of the main isolation insulation layer between the two adjacent contact plugs at the second vertical level.

11. A semiconductor memory device comprising:
a bit line extending in a first horizontal direction;
a word line extending in a second horizontal direction differing from the first horizontal direction, on the bit line;
a back gate electrode extending in the second horizontal direction on the bit line and disposed apart from the word line in the first horizontal direction;
a contact plug in which a first conductive pattern and a second conductive pattern each including a semiconductor material and a third conductive pattern and a fourth conductive pattern each including a metal-based material are sequentially stacked, on the word line and the back gate electrode;
a contact isolation insulation layer surrounding the contact plug and including a lower portion having a first minimum horizontal width in the first horizontal direction and an upper portion having a second minimum horizontal width in the first horizontal direction which is greater than the first minimum horizontal width, on the word line and the back gate electrode;
a channel pattern including a first end connected to the bit line and a second, opposite end connected to the first conductive pattern of the contact plug and extending in a vertical direction, the channel pattern disposed between the word line and the back gate electrode; and
a capacitor including a lower electrode connected to the fourth conductive pattern of the contact plug, an upper electrode on the lower electrode, and a capacitor dielectric layer disposed between the lower electrode and the upper electrode,
wherein a boundary between the lower portion and the upper portion of the contact isolation insulation layer is disposed at a vertical level which is lower than an upper surface of the third conductive pattern and higher than a lower surface of the third conductive pattern.

12. The semiconductor memory device of claim 11, wherein the contact isolation insulation layer comprises a main isolation insulation layer, including a first portion having the first minimum horizonal width in the first horizontal direction and a second portion having a third minimum horizontal width in the first horizontal direction, which is less than the first minimum horizontal width, on the first portion, and a sub isolation insulation layer disposed between an upper partial portion of the contact plug and the second portion of the main isolation insulation layer, and
an upper surface of the main isolation insulation layer, an upper surface of the sub isolation insulation layer, and an upper surface of the fourth conductive pattern form a coplanar surface.

13. The semiconductor memory device of claim 12, wherein the sub isolation insulation layer extends to a region between the third conductive pattern and the main isolation insulation layer from a region between the fourth conductive pattern and the main isolation insulation layer.

14. The semiconductor memory device of claim 13, wherein a lower surface of the sub isolation insulation layer is disposed at a vertical level which is lower than the upper surface of the third conductive pattern and higher than the lower surface of the third conductive pattern.

15. The semiconductor memory device of claim 13, wherein a portion of a lower surface of the sub isolation insulation layer is adjacent to the first portion of the main isolation insulation layer, and a portion of the lower surface of the sub isolation insulation layer contacts the third conductive pattern.

16. The semiconductor memory device of claim 13, wherein:
the sub isolation insulation layer has a ring shape in a plan view,
an inner surface of the sub isolation insulation layer covers a side surface of the second portion of the main isolation insulation layer, and
an upper portion of an outer surface of the sub isolation insulation layer contacts the fourth conductive pattern, and a lower portion thereof contacts the third conductive pattern.

17. The semiconductor memory device of claim 12, wherein:
the contact isolation insulation layer further comprises an interface insulation layer disposed between the main isolation insulation layer and the sub isolation insulation layer, each of the main isolation insulation layer and the sub isolation insulation layer comprises nitride, and
the interface insulation layer comprises oxide.

18. A semiconductor memory device comprising:
a bit line extending in a first horizontal direction;
a plurality of contact plugs where a first conductive pattern and a second conductive pattern each including a semiconductor material and a third conductive pattern and a fourth conductive pattern each including a metal-based material are sequentially stacked;
a plurality of channel patterns, each disposed between the bit line and a respective first conductive pattern of a respective one of the plurality of contact plugs and extending in a vertical direction;
a plurality of word lines and a plurality of back gate electrodes each extending in a second horizontal direction perpendicular to the first horizontal direction between the bit line and the plurality of contact plugs and disposed apart from one another with the plurality of channel patterns therebetween;
a contact isolation insulation layer surrounding the plurality of contact plugs, on the plurality of channel patterns, the plurality of word lines, and the plurality of back gate electrodes, the contact isolation insulation layer including a main isolation insulation layer, including a plurality of first portions, each first portion at a first height above the bit line and having a first minimum horizontal width between two adjacent channel patterns in the first horizontal direction and including a plurality of second portions, each second portion at a second height above the bit line and below the first height and having a second minimum horizontal width between two adjacent channel patterns greater than the first minimum horizontal width, each second portion on a respective first portion, and a plurality of sub isolation insulation layers disposed between an upper partial portion of each of the plurality of contact plugs and the second portions of the main isolation insulation layer; and
a plurality of capacitors including a plurality of lower electrodes respectively connected to the fourth conductive patterns of the plurality of contact plugs, an upper electrode on the plurality of lower electrodes, and a capacitor dielectric layer disposed between the plurality of lower electrodes and the upper electrode,
wherein the plurality of sub isolation insulation layers contact an upper partial portion of the third conductive pattern of each of the plurality of contact plugs and contact the fourth conductive pattern.

19. The semiconductor memory device of claim 18, wherein:
an upper surface of the main isolation insulation layer, an upper surface of each of the plurality of sub isolation insulation layers, and an upper surface of the fourth conductive pattern form a coplanar surface,
the plurality of sub isolation insulation layers extend to a region between the third conductive pattern and the main isolation insulation layer from a region between the fourth conductive pattern and the main isolation insulation layer, and
a lower surface of each of the plurality of sub isolation insulation layers is disposed at a vertical level which is lower than an upper surface of the third conductive pattern and higher than a lower surface of the third conductive pattern.

20. The semiconductor memory device of claim 18, wherein:
the second portions of the main isolation insulation layer comprise at least one void or slit, and
the plurality of sub isolation insulation layers fill the at least one void or slit.
